(19) United States
(12) Patent Application Publication
(10) Pub. No.: US 2024/0120358 A1
(43) Pub. Date: Apr. 11, 2024

(54) SOLID-STATE IMAGING DEVICE, METHOD FOR MANUFACTURING SOLID-STATE IMAGING DEVICE, AND ELECTRONIC APPARATUS

(71) Applicant: Brillnics Singapore Pte. Ltd., Singapore (SG)

(72) Inventors: Saswatee BANERJEE, Tokyo (JP); Junichi NAKAMURA, Shinagawa-ku, Tokyo (JP)

(21) Appl. No.: 18/263,677

(22) PCT Filed: Feb. 3, 2022
(86) PCT No.: PCT/JP2022/004214

§ 371 Date: Jul. 31, 2023

(30) Foreign Application Priority Data
Feb. 5, 2021 (JP) 2021- 017208

(51) Int. Cl. H01L 27/146

(52) U.S. Cl. CPC H01L 27/14627; H01L 27/1462; H01L 27/14645; G02B 27/4205

(57) ABSTRACT

A pixel part 20 includes a pixel array 210 in which a plurality of photoelectric conversion parts 2111 to 2114 are arranged, and a lens part array 220 including a plurality of lens parts LNS220 each of which is arranged corresponding to one side of the corresponding photoelectric conversion part 2111 (to 2114) of the pixel array 210, each lens part condensing incident light onto the correspondingly arranged photoelectric conversion part 2111 (to 2114) to cause the light to enter the photoelectric conversion part from the one side of the photoelectric conversion part. The lens part array 220, in which the lens parts LNS 220 are integrally formed with an optical film FLM 220, is bonded to the light incident side of the pixel array 210 to stack in Z direction.

### TECHNICAL FIELD

The present invention relates to a solid-state imaging device, a method for manufacturing a solid-state imaging device, and an electronic apparatus.

### BACKGROUND

Solid-state imaging devices (image sensors) including photoelectric conversion elements for detecting light and generating charges are embodied as CMOS (complementary metal oxide semiconductor) image sensors, which have been in practical use. The CMOS image sensors have been widely applied as parts of various types of electronic apparatuses such as digital cameras, video cameras, surveillance cameras, medical endoscopes, personal computers (PCs), mobile phones and other portable terminals (mobile devices).

A common CMOS image sensor captures color images using three primary color filters for red (R), green (G), and blue (B) or four complementary color filters for cyan, magenta, yellow, and green.

In general, each pixel in a CMOS image sensor has one or more filters. A CMOS image sensor includes a plurality of pixel groups arranged two-dimensionally. Each pixel group serves as a multi-pixel forming an RGB sensor and includes four filters arranged in a square geometry, that is, a red (R) filter that mainly transmits red light, green (Gr, Gb) filters that mainly transmit green light, and a blue (B) filter that mainly transmits blue light.

The design of the CMOS image sensor disclosed by Japanese Patent Application Publication No. 2017-139286 can be applied for any color filters (CFs), for example, R, G, B, IR pass (850 nm, 940 nm NIR light) pixels, clear (M: Monochrome) pixels with no color filter in the visible spectrum, or pixels of cyan, magenta, yellow and the like. Each pixel in a pixel group may have one or more on-chip color filter layers. For example, any pixel can have a double-layered color filter structure formed by combining together an NIR filter that cuts off or passes the IR at a specific wavelength or within a specific wavelength range and an R, G or B layer.

To implement autofocus (AF) function, image capturing devices such as digital cameras employ phase detection auto focus (PDAF) such as image plane phase detection, according to which some of the pixels in the pixel array are phase detection pixels for obtaining phase information for the autofocus (AF) purposes.

In the image-plane phase detection method, for example, half of the light-receiving region of each phase detection pixel is shielded by a light-shielding film. A phase difference on the image is detected using the phase detection pixel that receives light in the right half and the phase detection pixel that receive light in the left half (see, for example, Japanese Patent No. 5157436).

In the image plane phase detection method using the light-shielding film, a decrease in aperture ratio of such phase detection pixels results in a significant sensitivity deterioration. Therefore they cannot be used as normal pixels for generating an image and so considered as defective pixels. Such defective pixels may cause image resolution deterioration and the like.

To solve the above drawbacks, developed is another phase detection method in which a photoelectric conversion part (photodiode (PD)) in a pixel is divided into two (two provided) instead of using the light shielding film. A phase difference is detected based on a phase difference between signals obtained by a pair of the photoelectric conversion parts (photodiodes) (for example, see Japanese Patent No. 4027113 and Japanese Patent No. 5076528). Hereinafter, this phase detection method is called a dual PD method. This phase detection method involves pupil-dividing the rays of light transmitted through an imaging lens to form a pair of divided images and detecting a pattern discrepancy (phase shift amount). In this way, the amount of defocusing of the imaging lens may be detected. In this method, the phase difference detection is unlikely to generate defective pixels, and it is also possible to use them to obtain adequate image signals by adding the signals from the divided photoelectric conversion parts (PD).

The pixel arrays of the various CMOS image sensors described above are composed of periodically-arranged pixel arrays with a pitch of several microns or less. Each pixel in the pixel array is basically covered with a microlens as a lens part that has a predetermined focal length and is provided on the incident side of the filter in order to converge (condense) more light on the Si surface (photodiode surface).

FIGS. 1A to 1C schematically show a configuration example of a solid-state imaging device (a CMOS image sensor) having a microlens for each pixel. FIG. 1A is a plan view schematically showing an example arrangement of constituents of a solid-state imaging device (a CMOS image sensor) formed as an RGB sensor. FIG. 1B is a simplified sectional view along the line x1-x2 in FIG. 1A. FIG. 1C is a simplified sectional view along the line y1-y2 in FIG. 1A.

In the solid-state imaging device 1 shown in FIGS. 1A to 1C, a multi-pixel MPXL1 is constructed such that a G pixel SPXLG1 (color pixel) with a green (G) filter FLT-G1 that mainly transmits green light, an R pixel SPXLR (color filter) with a red (R) filter FLT-R that mainly transmits red light, a B pixel SPXLB (color filter) with a blue (B) filter FLT-B that mainly transmits blue light, and a G pixel SPXLG2 (color pixel) with a green (G) filter FLT-G2 that mainly transmits green light. These four pixels are arranged in two rows and two columns in a square geometry.

In the multi-pixel MPXL1, an oxide film OXL is formed between a light incident surface of a photoelectric converting region PD (1-4) and a light exiting surface of the filters. The light incident portion of the photoelectric converting region PD of the multi-pixel MPXL1 is divided (segmented) into a first photoelectric converting region PD1, a second photoelectric converting region PD2, a third photoelectric converting region PD3 and a fourth photoelectric converting region PD4, which respectively correspond to the color pixels SPXLG1, SPXLR, SPXLB, and SPXLG2. More specifically, the light entering portion of the photoelectric converting region PD is divided into four portions by a back side metal (BSM), which serves as a back-side separating part. In the example shown in FIGS. 1A to 1C, the back side metal BSM is formed at the boundaries between the color pixels SPXLG1, SPXLR, SPXLB, and SPXLG2 such that the back side metal BCM protrudes from the oxide film OXL into the filters. Additionally, in the photoelectric converting region PD, a back side deep trench isolation (BDTI) may be formed as a trench-shaped back side separation such that the BDTI is aligned with the back side metal (BSM) in the depth direction of the photoelectric converting region PD. In this way, the G pixel SPXLG1 includes the first photoelectric converting region PD1, the R pixel SPXLR includes the second photoelectric converting region PD2, the B pixel SPXLB include the third photoelectric converting region PD3, and the G pixel SPXLG2 includes the fourth photoelectric converting region PD4.

In the solid-state imaging device 1, the color pixels have, at the light entering side of the filter, corresponding microlenses MCL1, MCL2, MCL3 and MCL4. The microlens MCL1 allows light to enter the first photoelectric converting region PD1 of the G pixel SPXLG1, the microlens MCL2 allows light to enter the second photoelectric converting region PD2 of the R pixel SPXLR, the microlens MCL3 allows light to enter the third photoelectric converting region PD3 of the B pixel SPXLB, and the microlens MCL4 allows light to enter into the fourth photoelectric converting region PD4 of the G pixel SPXLG2.

In the multi-pixel MPXL1, one or two microlenses MCL are shared between the four color pixels SPXLG1, SPXLR, SPXLB and SPXLG2 that are arranged in the square geometry of 2×2. Any of the pixels may have any other color filters and be configured as any color pixels.

In this solid-state imaging device (CMOS image sensor) in which multiple pixels share a single microlens, distance information can be obtained from all of the pixels and each can have a PDAF (Phase Detection Auto Focus) function.

Most CMOS image sensors nowadays use smaller sized pixels to increase resolution. As pixel size decreases, it becomes more important to converge light efficiently. In line with this, it is important for the CMOS image sensors with microlenses to control the focal length of the microlens. Here, we discuss the control of the focal length of microlens used in the CMOS image sensors.

FIGS. 2A and 2B illustrate the control of the focal length of the microlens used in a CMOS image sensor. FIG. 2A is a simplified sectional view of the CMOS image sensor that has a microlens for each pixel, showing a schematic configuration example of one pixel. FIG. 2B illustrates the shape and focal length of the microlens. The basic configuration of the multi-pixel MPXL1A of FIG. 2A is same as that of FIG. 1, except that the microlens MCL is formed on a substrate BS1.

In FIG. 2B, “h” is the height (width) of the microlens (μ-lens) MCL, “n” is the refractive index of the microlens MCL, “n1” is the refractive index of the medium (air) on the light incident side, “n2” is the refractive index of the medium on the pixel side, “r1” is the radius of curvature (RoC) of a first surface MS1 of the microlens MCL on the light incident side, “r2” is the radius of curvature (∞ in this example) of a second surface MS2 of the microlens MCL on the light-exiting side, and “f” is the focal length of the microlens MCL.

The focal length “f” of the microlens MCL is determined by the radius of curvature “r1” and the material of the microlens MCL. For the microlens array in the pixel array, the focal length “f” and the position of the focal point can be changed by changing the radius of curvature RoC of the microlens MCL or by changing the thickness of the microlens substrate layer BS1.

The radius of curvature RoC of the microlens MCL is determined by the height of the microlens MCL. As process conditions, there is a maximum limit for the height “h” of the microlens MCL. The refractive index “n1” of the most commonly used material for the microlens MCL is 1.6 or smaller. As mentioned above, the process conditions and the refractive index of the material determine the minimum focal length f of the microlens MCL. Therefore, to reduce the focal length f, it is necessary to consider the complex design and process conditions such as inner-layer lenses.

### Control of Light Loss Due to Reflection from Microlens Surface

As mentioned above, the microlens MCL is formed of an optically transparent material with a refractive index n1 of 1.6 or less. When light enters on the surface MS1 of the microlens MCL, some of rays of the light is lost due to reflection on the surface MS1 of the microlens MCL. An interface is formed between a medium of low refractive index (1.0, air) and a medium of high refractive index (microlens). The actual amount of the reflection loss depends on the angle and wavelength of the incident light.

For the CMOS image sensors, the reflection loss can become extremely large at large incident angles, such as 30 degrees. This results in low responsiveness at large incident angles. However, some applications require high responsiveness at large incident angles.

### RELEVANT REFERENCE

### List of Relevant Patent Literature

Patent Literature 1: Japanese Patent Application Publication No. 2017-139286
Patent Literature 2: Japanese Patent No. 5157436
Patent Literature 3: Japanese Patent No. 4027113
Patent Literature 4: Japanese Patent No. 5076528
Patent Literature 5: United States Patent Application Publication No. 2007/0035844 A1
Patent Literature 6: U.S. Ser. No. 10/310,144 B2

### SUMMARY

However, there are the following disadvantages for the solid-state imaging device (CMOS image sensor) that includes the microlens for each pixel.

As discussed above, the solid-state imaging devices (CMOS image sensors) may have microlenses, and there are the following limitations on the performance of the microlens MCL due to the process conditions and other factors. More specifically, production of the microlens MCLs is significantly constrained by the focal length dependence, the radius of curvature of the refractive surface limited by the process conditions, the optical properties of the lens material, and the availability of the material compatible with a lithography process. Furthermore, the size of the focal spot is limited by diffraction and lens aberrations.

In production of a lens part array including the microlenses as a lens part subject to many such constraints, it is necessary to select the constraint conditions for microlenses and adjust the focal length within the array separately for each microlens, which requires complicated and time-consuming work.

As mentioned above, the microlens MCL has the maximum limit for its height “h” under the process conditions. In addition, the refractive index n1 of the most commonly used material for the microlenses MCL is 1.6 or smaller. This automatically limits the maximum achievable radius of curvature RoC and focal length f of the microlens MCL.

In the conventional process, the microlens MCL is formed and disposed on the substrate layer BS1 of the transparent material with the same optical properties as the microlens, as shown in FIG. 2A. The focal point can be adjusted by changing the thickness of the substrate layer BS1.

To reduce the focal length “f”, it is necessary to consider the complex design and process conditions such as inner-layer lenses.

In particular, a function to control the focal length and the shape, size, and position of the focal spot is highly desirable in various applications of the CMOS image sensors, such as digital still cameras and PDAFs for AR/VR. For example, depending on the applications, it is desirable to make the focal spot as small as possible in terms of the optical design of the sensor. It is also desirable to determine where to place the focal spot (e.g., on the PD surface or on the backside metal BSM which is a metal grid) to satisfy certain optical characteristics.

In conventional CMOS image sensors, an antireflection layer is formed on the light incident surface of the microlens MCL (see, for example, Patent Literatures 5 and 6). However, for these CMOS image sensors, it is necessary to fabricate the antireflection layer for the light incident surface of each microlens, which further complicates the fabrication process of the lens array.

In recent years, it is desired to improve the microlens shift and the light condensing characteristics of the microlenses so that the CMOS image sensors can receive rays of light from different incident angles without uneven sensitivity.

Some of current technical issues related to the microlens arrays are further discussed with reference to FIGS. 3A to 4B. FIGS. 3A and 3B illustrate technical issues related to PDAF/normal pixels. FIGS. 4A and 4B illustrate technical issues related to PDAF pixels with a metal shield.

Conventional microlens arrays used in CIS pixels are subject to a lens shading effect. Shading is caused by converging behavior of the microlens at large Chief Ray Angles (CRAs). To improve the shading effect, the position of the microlens is shifted from the center toward the edge of the pixel plane depending on the CRA. This is known as microlens shift.

The microlens arrays are used to converge the incident light on the photoelectric converting region PD. The arrangement of the microlenses MCL is adjusted by the microlens shift to correct for the lens shading effect (reduced QE at the edges of the image plane) at large CRAs. As shown in FIG. 3A, incidence at the CRA can degrade performance since the focal point shifts on the aperture (aperture) APTR/metal shield MTLS plane. To maintain the performance at the CRA, the microlens shift is applied as shown in FIG. 3B. The microlens shift to compensate for the performance degradation occurring at the incidence with a large CRA can restore the position of the focal point and make it symmetric with respect to the center, but it is difficult to control the shape distortion of the focus.

The current focusing mechanism of the microlens arrays has mainly five issues stated below as the first to fifth issues. Note that the third to fifth issues are relating to the PDAF design.

First Issue

In a pixel, some of rays of light is lost due to reflection R from the surface of the microlens MCL, as shown in FIGS. 3A and 4B. This is because in conventional designs, the surface of the microlens MCL is coated with a single thin layer, which can provide anti-reflection only in a narrow wavelength band and a narrow range of angles.

Second Issue

The microlens array uses converging elements (MCLs) of the same shape anywhere in the image plane. Therefore, it is difficult to mitigate poor performance at the edges of the image plane with the microlens shift alone.

### Issues Inherent in PDAF Design with Metal Shield/Dual PD

Third Issue

Adjusting the shape/size of the focal spot: In designs using the metal shield, it may be desirable to design the shape and size of the focal spot in a way that controls the amount of forward and backward scattering of light entering the aperture. This will help minimize the negative impacts of related effects such as crosstalk, flare, and stray light on the image quality.

Forth Issue

Adjustment of the focal distance and the position of the focus along the z-axis: It is important to adjust the focal distance and position of the focus along the z-direction. In one example, the light should be focused on the plane of the metal shield. This can be done by increasing the curvature of the microlens MCL surface (MCL height) or the thickness of the substrate layer BS1 of the microlens MCL. However, a thick substrate layer BS1 may increase crosstalk. There are other more complex methods, such as employing in-layer lenses to bring the focus to the desired position. However, these alternative methods are usually expensive and difficult to realize.

Fifth Issue

Adjustment of the shape of the converging element: It is desirable that the shape of the microlens be designed such that a desired portion of the imaging lens exit pupil is visible. This is difficult to achieve with existing techniques in which the shape of the microlens MCL is unchanged.

The present invention provides a solid-state imaging device, a method of manufacturing a solid-state imaging device, and electronic equipment with which a lens part array can be fabricated without requiring complicated work, which in turn facilitates the fabrication of a pixel part, and with which microlens shift and the light condensing characteristics of the microlenses can be improved. The present invention also provides a solid-state imaging device, a method for manufacturing a solid-state imaging device, and electronic equipment with which it is possible to fabricate a lens part array without requiring complicated woks, and with which it is possible to reduce reflection loss on a light-incident surface of a lens part. Further it is possible to facilitate the fabrication of a pixel part and improve lens shift and light condensing characteristics of the lens.

A solid-state imaging device according to one aspect of the invention includes a pixel part in which a plurality of pixels configured to perform photoelectric conversion are arranged in an array. The pixel part includes: a pixel array in which a plurality of photoelectric conversion parts are arranged in an array, each photoelectric conversion part photoelectrically converting light of a predetermined wavelength incident from one side thereof; and a lens part array including a plurality of lens parts arranged in an array, each lens part being disposed corresponding to one side of the corresponding photoelectric conversion part of the pixel array, each lens part condensing incident light onto the correspondingly arranged photoelectric conversion part to cause the light to enter the photoelectric conversion part from the one side of the photoelectric conversion part. The lens part array includes at least one optical film having predetermined optical function parts at least in a region where the lens parts are to be formed, the optical film is formed in a single body to extend over a plurality of the lens parts at least in a part of the lens part array.

According to a second aspect of the invention, provided is a method for manufacturing a solid-state imaging device. The solid-state imaging device has a pixel part in which a plurality of pixels configured to perform photoelectric conversion are arranged in an array. The pixel part includes: a pixel array and a pixel part in which a plurality of pixels configured to perform photoelectric conversion are arranged in an array. The method includes: a pixel array fabrication step in which pixels are fabricated in an array, each pixel including a photoelectric conversion part that photoelectrically converts light of a predetermined wavelength incident from one side; and a lens part array fabrication step in which lens parts are fabricated in an array, each lens part being disposed corresponding to one side of the corresponding photoelectric conversion part of the pixel array, each lens part condensing incident light onto the corresponding photoelectric conversion part to cause the light to enter the photoelectric conversion part from the one side of the photoelectric conversion part. The lens part array fabrication step includes an optical film forming step in which at least one optical film having predetermined optical function parts at least in a region where the lens parts are to be formed is formed. The optical film is formed in a single body to extend over a plurality of the lens parts at least in a part of the lens part array.

An electronic apparatus according to a third aspect of the invention includes a solid-state imaging device, and an optical system for forming a subject image on the solid-state imaging device. The solid-state imaging device includes a pixel part in which a plurality of pixels are arranged in an array, each pixel being configured to perform photoelectric conversion. The pixel part includes: a pixel array in which a plurality of photoelectric conversion parts are arranged in an array, each photoelectric conversion part photoelectrically converting light of a predetermined wavelength incident from one side thereof; and a lens part array including a plurality of lens parts arranged in an array, each lens part being disposed corresponding to one side of the corresponding photoelectric conversion part of the pixel array, each lens part condensing incident light onto the correspondingly arranged photoelectric conversion part to cause the light to enter the photoelectric conversion part from the one side of the photoelectric conversion part. The lens part array includes at least one optical film having predetermined optical function parts at least in a region where the lens parts are to be formed, the optical film is formed in a single body to extend over a plurality of the lens parts at least in a part of the lens part array.

### Advantageous Effects

According to the aspects of the invention, it is possible to fabricate a lens part array without requiring complicated work, which in turn facilitates the manufacture of a pixel part, and with which microlens shift and the light condensing characteristics of the microlenses can be improved. Further, according to the aspects of the invention, it is possible to fabricate a lens part array without requiring complicated woks, and with which it is possible to reduce reflection loss on a light-incident surface of a lens part. Further it is possible to facilitate the fabrication of the pixel part and improve lens shift and light condensing characteristics of the lens.

### BRIEF DESCRIPTION OF THE DRAWINGS

FIG. 1A to 1C schematically show an example configuration of a solid-state imaging device (CMOS image sensor) in which a microlens is provided for each pixel.

FIGS. 2A and 2B illustrate a control of a focal length of the microlens used in the CMOS image sensor.

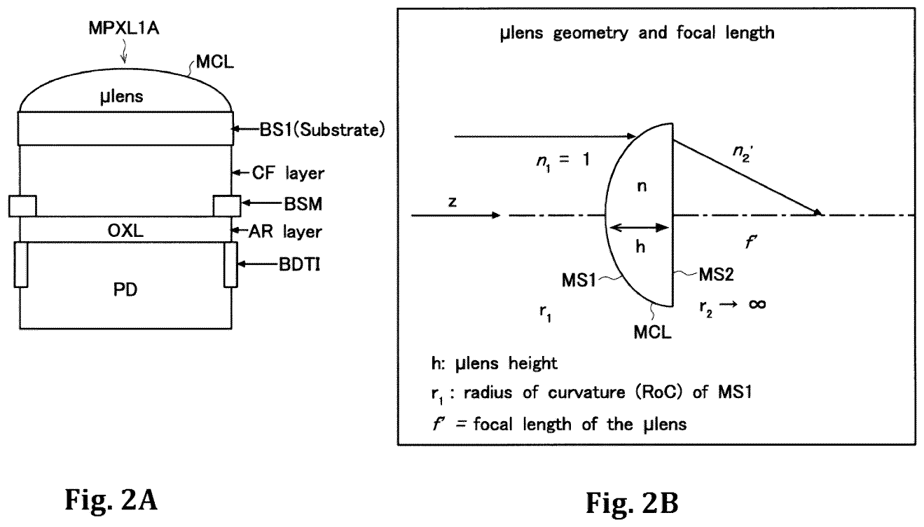

FIGS. 3A and 3B illustrate technical issues relating to PDAF/normal pixels.

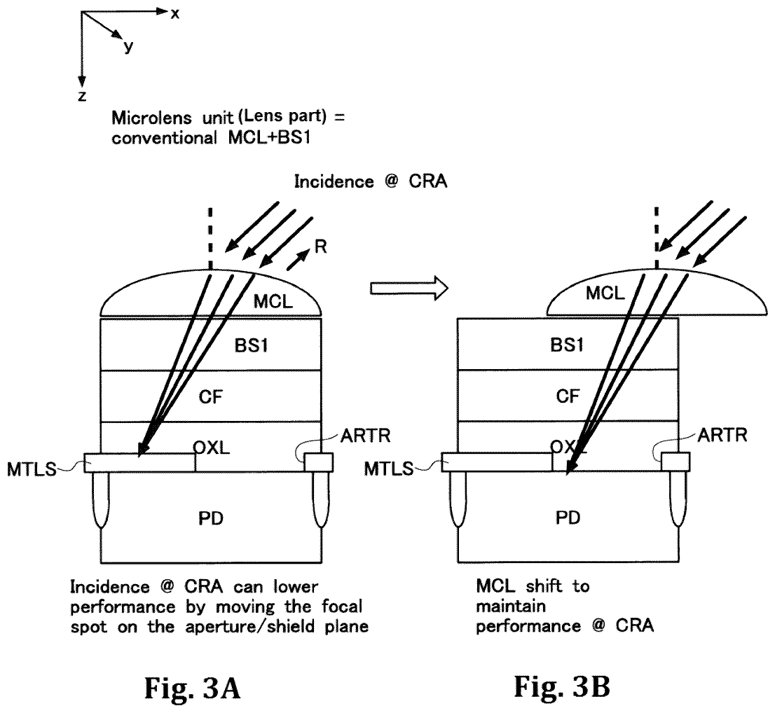

FIG. 4 is a block diagram showing an example configuration of a solid-state imaging device according to a first embodiment of the present invention.

FIG. 5 is a circuit diagram showing an example of a multi-pixel in which one floating diffusion is shared by four pixels in a pixel part of the solid-state imaging device according to the first embodiment of the present invention.

FIGS. 6A to 6C show example configurations of a column signal processing circuit in a reading circuit according to the embodiments of the invention.

FIGS. 7A to 7C schematically shows an example configuration of the pixel part of the solid-state imaging device (a CMOS image sensor) according to the first embodiment of the present invention.

FIG. 8 is a schematic plan view showing a configuration of a lens part array in the pixel part according to the first embodiment of the invention.

FIG. 9 illustrates a schematic configuration of the lens part according to the first embodiment of the invention.

FIGS. 10A to 10D illustrate other schematic configurations of the lens part according to the first embodiment of the invention.

FIGS. 11A and 11B illustrate comparison of a shading suppression effect of a pixel array of the first embodiment of the invention with the shading suppression effect of a comparative example pixel array.

FIG. 12 is an example of an apparatus for manufacturing the lens part array according to the first embodiment of the invention.

FIG. 13 schematically illustrates a manufacturing method of the pixel part of the solid-state imaging device according to the first embodiment of the invention.

FIG. 14 schematically illustrates a configuration of a lens part in a pixel part of a solid-state imaging device (CMOS image sensor) according to a second embodiment of the invention.

FIGS. 15A to 15D illustrate other schematic configurations of the lens part according to the second embodiment of the invention.

FIG. 16 schematically illustrates a configuration of a lens part in a pixel part of a solid-state imaging device (CMOS image sensor) according to a third embodiment of the invention.

FIG. 17 schematically illustrates a configuration of a lens part in a pixel part of a solid-state imaging device (CMOS image sensor) according to a fourth embodiment of the invention.

FIG. 18A to FIG. 18B illustrate an application example of a solid-state imaging device according to the fourth embodiment of the invention.

FIGS. 19A to 19C schematically illustrate a configuration of a lens part in a pixel part of a solid-state imaging device (CMOS image sensor) according to a fifth embodiment of the invention.

FIGS. 20A to 20D illustrate a schematic configuration example of a solid-state imaging device (CMOS image sensor) relating to a sixth embodiment of the invention, showing structures and functions of an existing microlens and a Fresnel zone plate (FZP) as a diffractive optical element that also serves as a microlens.

FIGS. 21A to 21E illustrate a schematic configuration example of a solid-state imaging device (CMOS image sensor) relating to a seventh embodiment of the invention, showing structures and functions of an existing microlens and a diffractive optical element (DOE) that also serves as a microlens.

FIGS. 22A to 22E illustrate a schematic configuration example of a solid-state imaging device (CMOS image sensor) relating to an eighth embodiment of the invention, showing structures and functions of an existing microlens and a diffractive optical element (DOE) that also serves as a microlens.

FIG. 23 schematically shows an example configuration of a solid-state imaging device (a CMOS image sensor) according to a ninth embodiment of the invention.

FIG. 24 shows an example of an AR (Anti-Reflection) structure formed on a film that can be employed as the fine structure of the ninth embodiment.

FIG. 25 schematically shows an example configuration of a solid-state imaging device (a CMOS image sensor) according to a tenth embodiment of the invention.

FIG. 26 shows an example configuration of an electronic apparatus to which the solid-state imaging devices relating to the embodiments of the present invention can be applied.

### DESCRIPTION OF THE EMBODIMENTS

Embodiments of the present invention will be hereinafter described with reference to the drawings.

### First Embodiment

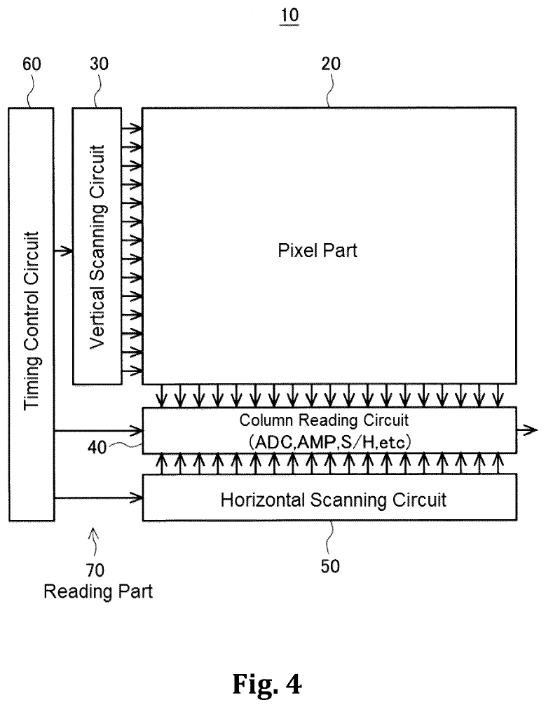

FIG. 4 is a block diagram showing an example configuration of a solid-state imaging device relating to a first embodiment of the present invention. In this embodiment, a solid-state imaging device 10 is constituted by, for example, a CMOS image sensor. The CMOS image sensor is, for example, applied to back-side illumination image sensor (BSI).

As shown in FIG. 4, the solid-state imaging device 10 is constituted mainly by a pixel part 20 serving as an image capturing part, a vertical scanning circuit (a row scanning circuit) 30, a reading circuit (a column reading circuit) 40, a horizontal scanning circuit (a column scanning circuit) 50, and a timing control circuit 60. Among these components, for example, the vertical scanning circuit 30, the reading circuit 40, the horizontal scanning circuit 50, and the timing control circuit 60 constitute a reading part 70 for reading out pixel signals.

In the solid-state imaging device 10 relating to the first embodiment, as will be described in detail below, a multi-pixel is constituted by at least two (four, in the first embodiment) pixels each having a photoelectric converting region and the multi-pixels are arranged in an array pattern in the pixel part 20. In this first embodiment, the pixel part 20 includes a pixel array in which the plurality of photoelectric conversion parts that photoelectrically convert light of a predetermined wavelength incident from one side are arranged in an array, and a lens part array including a plurality of lens parts that are arranged in an array to correspond to the photoelectric conversion parts of the pixel array on one side. Each lens part condenses rays of incident light onto the one side of the correspondingly arranged photoelectric conversion part to let the light enter the photoelectric conversion part.

In the embodiment, the lens part array includes a single optical film having predetermined optical function parts at least in a region where the lens parts are to be formed, the optical film is formed in a single body to extend over a plurality of the lens parts at least in a part of the lens part array (the entire array in the embodiment). In the first embodiment, the lens part includes a film-integrated (film-integrally formed) optical element that is integrally formed with the optical film as the optical function part and that condenses rays of incident light onto the correspondingly arranged photoelectric conversion part to cause the light to enter the photoelectric conversion part from the one side of the photoelectric conversion part. In the first embodiment, the film-integrated optical element is an aspherical microlens whose shape varies depending on the position of the corresponding pixel in the pixel array. The aspherical microlens can be formed of, for example, a microprism as a prismatic optical element having two or more non-parallel planes. In the first embodiment, the aspherical microlens can also be formed of a polypyramid whose apex is positioned on the light incident side.

In this embodiment, the film-integrated optical element may be exemplified by diffractive optical elements including Fresnel lenses, binary elements, and holographic optical elements that use diffraction, in addition to the aspherical microlenses described above that use refraction of light.

In the first embodiment, the multi-pixel is formed as an RGB sensor as an example.

A description will be hereinafter given of an outline of the configurations and functions of the parts of the solid-state imaging device 10 and then details of configurations and arrangement of the multi-pixel and the like in the pixel part 20.

### Configurations of Pixel Part 20 and Multi-Pixel MPXL20

In the pixel part 20, a plurality of multi-pixels each including a photodiode (a photoelectric conversion part) and an in-pixel amplifier are arranged in a two-dimensional matrix comprised of N rows and M columns.

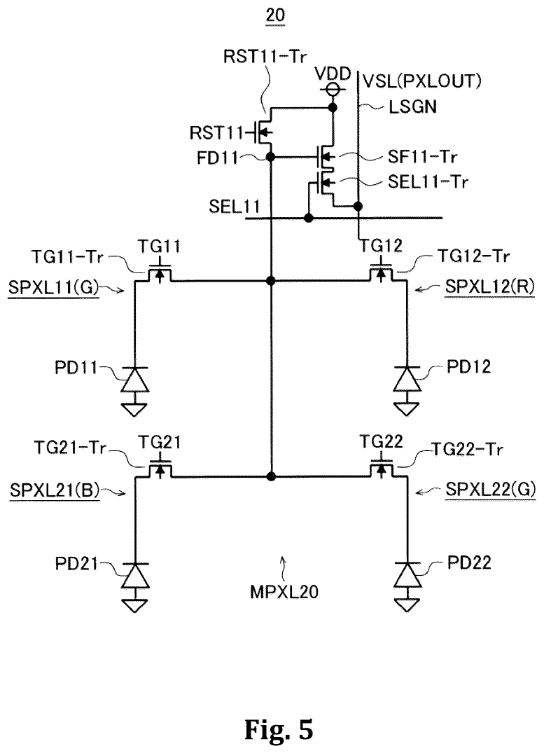

FIG. 5 is a circuit diagram showing an example of a multi-pixel in which one floating diffusion is shared by four pixels in a pixel part of the solid-state imaging device relating to the first embodiment of the invention.

In the pixel part 20 of FIG. 5, a multi-pixel MPXL20 includes four pixels (color pixels in the embodiment), a first color pixel SPXL11, a second color pixel SPXL12, a third color pixel SPXL21, and a fourth color pixel SPXL22, arranged in a square geometry of 2×2.

The first color pixel SPXL11 includes a photodiode PD11 formed by a first photoelectric converting region and a transfer transistor TG11-Tr.

The second color pixel SPXL12 includes a photodiode PD12 formed by a second photoelectric converting region and a transfer transistor TG12-Tr.

The third color pixel SPXL21 includes a photodiode PD21 formed by a third photoelectric converting region and a transfer transistor TG21-Tr.

The fourth color pixel SPXL22 includes a photodiode PD22 and a transfer transistor TG22-Tr.

In the multi-pixel MPXL 20 of the pixel part 20, the four color pixels SPXL11, SPXL12, SPXL21, SPXL22 share a floating diffusion FD11, a reset transistor RST11-Tr, a source follower transistor SF11-Tr, and a selection transistor SEL11-Tr.

In such a four-pixel sharing configuration, for example, the first color pixel SPXL11 is formed as a G (green) pixel, the second color pixel SPXL12 is formed as an R (red) pixel, the third color pixel SPXL21 is formed as a B (blue) pixel, and the fourth color pixel SPXL22 is formed as a G (green) pixel. For example, the photodiode PD11 of the first color pixel SPXL11 operates as a first green (G) photoelectric conversion part, the photodiode PD12 of the second color pixel SPXL12 operates as a red (R) photoelectric conversion part, the photodiode PD21 of the third color pixel SPXL21 operates as a blue (B) photoelectric conversion part, and the photodiode PD22 of the fourth pixel SPXL22 operates as a second green (G) photoelectric conversion part.

The photodiodes PD11, PD12, PD21, and PD22 are, for example, pinned photodiodes (PPDs). On the substrate surface for forming the photodiodes PD11, PD12, PD21, PD22, there is a surface level due to dangling bonds or other defects, and therefore, a lot of charges (dark current) are generated due to heat energy, so that a correct signal fails to be read out. In a pinned photodiode (PPD), a charge accumulation part of the photodiode PD can be buried in the substrate to reduce mixing of the dark current into signals.

The photodiodes PD11, PD12, PD21, and PD22 generate signal charges (here, electrons) in an amount determined by the quantity of the incident light and store the same. A description will be hereinafter given of a case where the signal charges are electrons and each transistor is an n-type transistor. However, it is also possible that the signal charges are holes or each transistor is a p-type transistor.

The transfer transistor TG11-Tr is connected between the photodiode PD11 and the floating diffusion FD11 and controlled through a control line (or a control signal) TG11. Under control of the reading part 70, the transfer transistor TG11-Tr remains selected and in the conduction state in a period in which the control line (or control signal) TG11 is at a predetermined high (H) level, to transfer charges (electrons) produced by photoelectric conversion and stored in the photodiode PD11 to the floating diffusion FD11.

The transfer transistor TG12-Tr is connected between the photodiode PD12 and the floating diffusion FD11 and controlled through a control line (or a control signal) TG12. Under control of the reading part 70, the transfer transistor TG12-Tr remains selected and in the conduction state in a period in which the control line TG12 is at a predetermined high (H) level, to transfer charges (electrons) produced by photoelectric conversion and stored in the photodiode PD12 to the floating diffusion FD11.

The transfer transistor TG21-Tr is connected between the photodiode PD21 and the floating diffusion FD11 and controlled through a control line (or a control signal) TG21. Under control of the reading part 70, the transfer transistor TG21-Tr remains selected and in the conduction state in a period in which the control line TG21 is at a predetermined high (H) level, to transfer charges (electrons) produced by photoelectric conversion and stored in the photodiode PD21 to the floating diffusion FD11.

The transfer transistor TG22-Tr is connected between the photodiode PD22 and the floating diffusion FD11 and controlled through a control line (or a control signal) TG22. Under control of the reading part 70, the transfer transistor TG22-Tr remains selected and in the conduction state in a period in which the control line TG22 is at a predetermined high (H) level to transfer charges (electrons) produced by photoelectric conversion and stored in the photodiode PD22 to the floating diffusion FD11.

As shown in FIG. 5, the reset transistor RST11-Tr is connected between a power supply line VDD (or a power supply potential) and the floating diffusion FD11 and controlled through a control line (or a control signal) RST11. Alternatively, the reset transistor RST11-Tr may be connected between a power supply line VRst different from the power supply line VDD and the floating diffusion FD and controlled through the control line (or the control signal) RST11. Under control of the reading part 70, during a scanning operation for reading, for example, the reset transistor RST11-Tr remains selected and in the conduction state in a period in which the control line (or control signal) RST11 is at the H level, to reset the floating diffusion FD11 to the potential of the power supply line VDD (or VRst).

The source follower transistor SF11-Tr and the selection transistor SEL11-Tr are connected in series between the power supply line VDD and a vertical signal line LSGN. The floating diffusion FD11 is connected to the gate of the source follower transistor SF11-Tr, and the selection transistor SEL11-Tr is controlled through a control line (or a control signal) SEL11. The selection transistor SEL11-Tr remains selected and in the conduction state in a period in which the control line (or control signal) SEL11 is at the H level. In this way, the source follower transistor SF11-Tr outputs, to the vertical signal line LSGN, a read-out voltage (signal) of a column output VSL (PIXOUT), which is obtained by converting the charges of the floating diffusion FD11 with a gain determined by the quantity of the charges (the potential) into a voltage signal.

The vertical scanning circuit 30 drives the pixels in shutter and read-out rows through the row-scanning control lines under control of the timing control circuit 60. Further, the vertical scanning circuit 30 outputs, according to address signals, row selection signals for row addresses of the read-out rows from which signals are to be read out and the shutter rows in which the charges accumulated in the photodiodes PD are reset.

In a normal pixel reading operation, the vertical scanning circuit 30 of the reading part 70 drives the pixels to perform shutter scanning and then reading scanning.

The reading circuit 40 includes a plurality of column signal processing circuits (not shown) arranged corresponding to the column outputs of the pixel part 20, and the reading circuit 40 may be configured such that the plurality of column signal processing circuits can perform column parallel processing.

The reading circuit 40 may include a correlated double sampling (CDS) circuit, an analog-digital converter (ADC), an amplifier (AMP), a sample/hold (S/H) circuit, and the like.

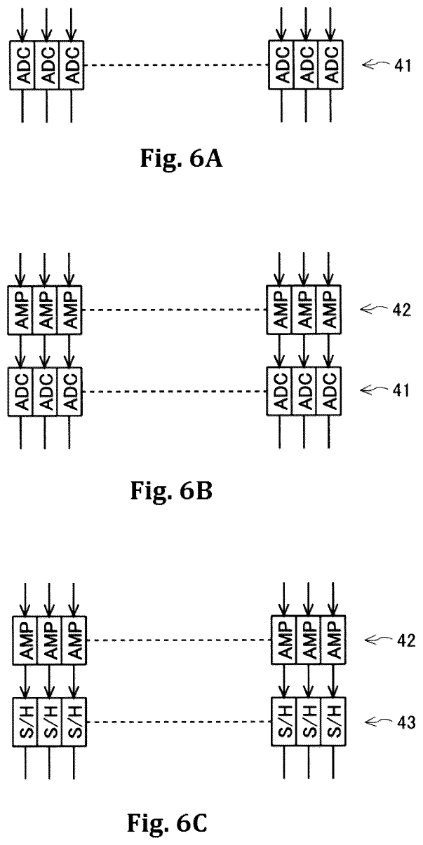

As mentioned above, as shown in FIG. 6A, for example, the reading circuit 40 may include ADCs 41 for converting the read-out signals VSL output from the respective columns of the pixel part 20 into digital signals. Alternatively, as shown in FIG. 6B, for example, the reading circuit 40 may include amplifiers (AMPs) 42 for amplifying the read-out signals VSL output from the respective columns of the pixel part 20. As yet another alternative, as shown in FIG. 6C, for example, the reading circuit 40 may include sample-and-hold (S/H) circuits 43 for sampling/holding the read-out signals VSL output from the respective columns of the pixel part 20.

The horizontal scanning circuit 50 scans the signals processed in the plurality of column signal processing circuits of the reading circuit 40 such as ADCs, transfers the signals in a horizontal direction, and outputs the signals to a signal processing circuit (not shown).

The timing control circuit 60 generates timing signals required for signal processing in the pixel part 20, the vertical scanning circuit 30, the reading circuit 40, the horizontal scanning circuit 50, and the like.

The above description has outlined the configurations and functions of the parts of the solid-state imaging device 10. Next, a detailed description will be given of the arrangement of the pixels in the pixel part 20 relating to the first embodiment.

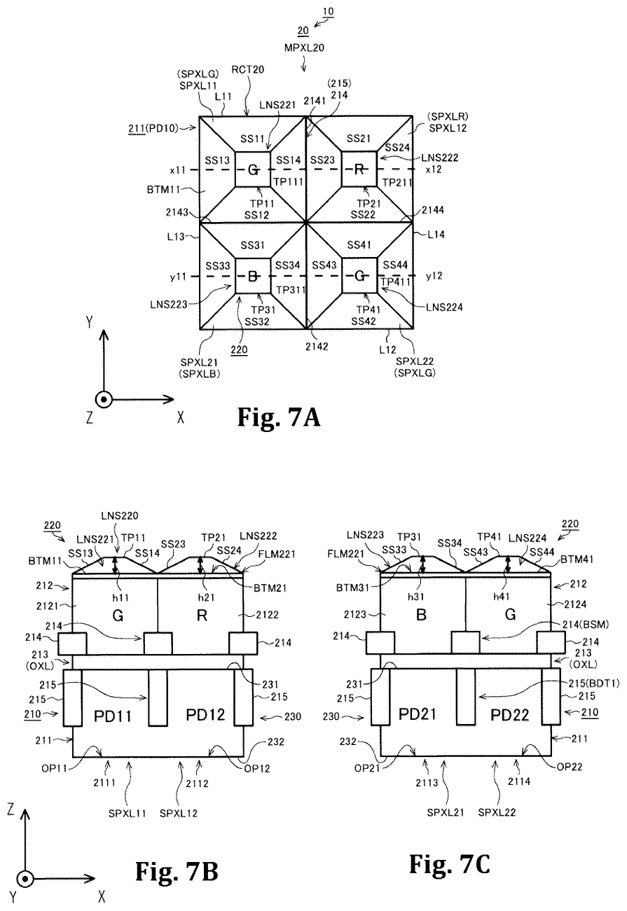

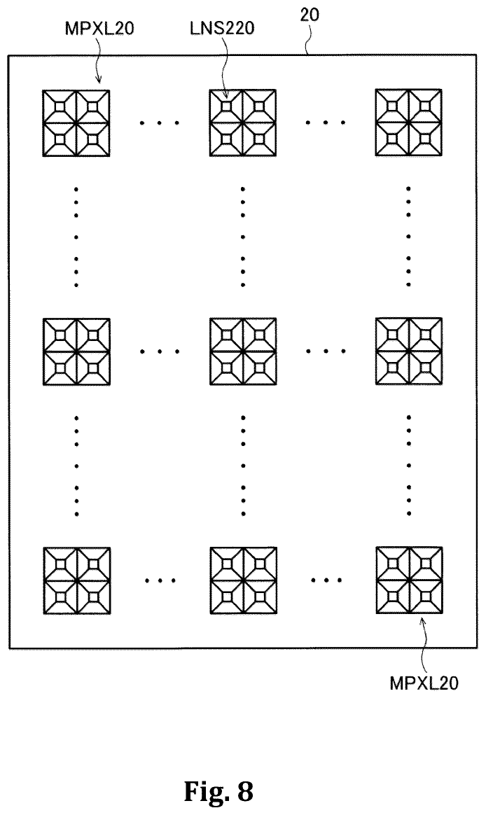

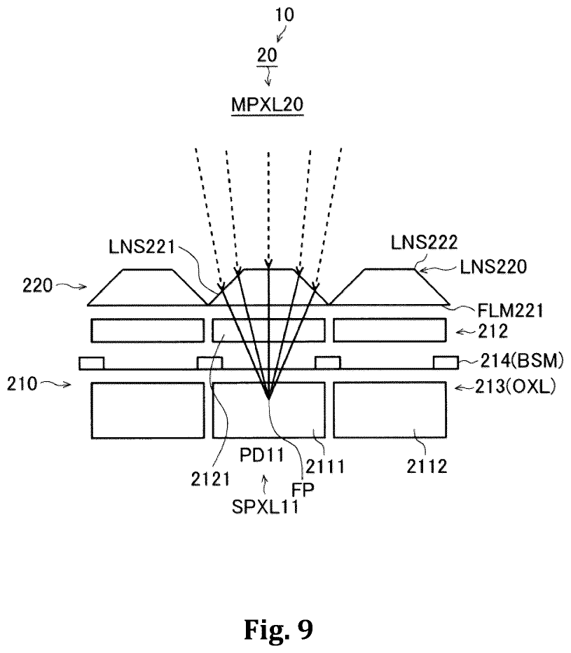

FIGS. 7A to 7C schematically show an example configuration of the pixel part of the solid-state imaging device (the CMOS image sensor) according to the first embodiment of the present invention. FIG. 7A is a plan view schematically showing an example arrangement of constituents of the pixel part of the solid-state imaging device (CMOS image sensor) formed as an RGB sensor. FIG. 7B is a simplified sectional view along the line x11-x12 in FIG. 7A. FIG. 7C is a simplified sectional view along the line y11-y12 in FIG. 7A. FIG. 8 is a schematic plan view showing a configuration of the lens part array in the pixel part according to the first embodiment of the invention. FIG. 9 illustrates a schematic configuration of the lens part in the pixel part according to the first embodiment of the invention.

In the present embodiment, a first direction refers to the column direction (the horizontal or X direction), row direction (the vertical or Y direction) or diagonal direction of the pixel part 20 in which a plurality of pixels are arranged in a matrix pattern. The following description is made with the first direction referring to the column direction (the horizontal or X direction), for example. Accordingly, a second direction refers to the row direction (the vertical or Y direction).

In this first embodiment, as shown in FIGS. 7A to 7C, the pixel part 20 includes a pixel array 210 in which the plurality of photoelectric conversion parts (may also be referred to as photoelectric converting regions) 2111, 2112, 2113, 2114 that photoelectrically convert light of a predetermined wavelength incident from one side are arranged in an array, and a lens part array 220 including a plurality of lens parts LNS220 (LNS221 to LNS224) that are arranged in an array and disposed corresponding to the one side of the corresponding photoelectric conversion parts 2111 (to 2114) of the pixel array 210. The lens parts LNS220 condenses the incident light onto the corresponding photoelectric conversion parts 211 (2111 to 2114) to cause the light to enter the photoelectric conversion part from one side of the corresponding photoelectric conversion parts 211. The pixel part 20 and the lens part array 220 are bonded and stacked to each other in the Z direction. The lens part array 220 is bonded to the pixel array 210 and the color filter array 212. In this example, as shown in FIG. 9, the lens part array 220, in which the lens parts LNS220 are integrally formed on the optical film FLM221, is bonded to the light incident side of the pixel array 210.

In the embodiment, As described above, the lens part array 220 includes one optical film FLM221 having predetermined optical function parts (for example, light condensing function) in a region where the lens parts LNS220 are to be formed, and the optical film FLM221 is formed in a single body to extend over a plurality of the lens parts LNS220 of the entire lens part array. In the first embodiment, the lens part LNS220 includes the microlenses LNS221, LNS222, LNS223, and LNS224 as film-integrated optical elements that are integrally formed with the first optical film FLM221 as the optical function parts and that condense the incident light onto the correspondingly arranged photoelectric conversion parts 2111 (to 2114) from one side of the photoelectric conversion parts (first substrate side 231). In the first embodiment, the microlenses LNS221, LNS222, LNS223, and LNS224 as the film-integrated optical elements are formed by, for example, prism-like optical elements (microprisms) having two or more non-parallel planes. In the first embodiment, the film-integrated microlenses LNS221 (to LNS224) are formed in a frustum (tetragonal frustum in this example) with the top facing the light incident side, as shown in FIG. 9.

The configuration of the microlens LNS221 (to LNS224) formed as such a film-integrated optical element will be described in detail later.

In the pixel part 20 of FIG. 7A, a multi-pixel MPXL20 includes four pixels (color pixels in the embodiment), a first color pixel SPXL11, a second color pixel SPXL12, a third color pixel SPXL21, and a fourth color pixel SPXL22, arranged in a square geometry of 2×2. More specifically, in the multi-pixel MPXL20, the first to fourth color pixels SPXL11, SPXL12, SPXL21 and SPXL22 are arranged in a square geometry such that the first color pixel SPXL11 is adjacent to the second color pixel SPXL12 in the first or X direction, the third color pixel SPXL21 is adjacent to the fourth color pixel SPXL22 in the first or X direction, the first color pixel SPXL11 is adjacent to the third color pixel SPXL21 in the second direction orthogonal to the first direction, or the Y direction and the second color pixel SPXL12 is adjacent to the fourth color pixel SPXL22 in the second or Y direction.

In the first embodiment, the first color pixel SPXL11 is formed as the G pixel SPXLG including a green (G) filter FLT-G that transmits mainly green light. The second color pixel SPXL12 is formed as an R pixel SPXLR that includes a red (R) filter FLT-R that transmits mainly red light. The third color pixel SPXL21 is formed mainly as a B color pixel SPXLB including a blue (B) filter FLT-B that transmits mainly blue light. The fourth color pixel SPXL22 is formed as the G pixel SPXLG including the green (G) filter FLT-G that transmits mainly green light.

The multi-pixel MPXL20 includes, as shown in FIGS. 8A, 8B and 8C, a photoelectric converting part 210, a lens part 211, a color filter part 212, an anti-reflective film 213, a first back side separating part 214, and a second back side separating part 215.

In the pixel array 210 of FIG. 7A, the light incident portion of the photoelectric conversion part 211 (PD10), which is a rectangular region RCT20 defined by four edges L11 to L14, is divided (segmented) into a first photoelectric converting region (PD11) 2111, a second photoelectric converting region (PD12) 2112, a third photoelectric converting region (PD21) 2113 and a fourth photoelectric converting region (PD22) 2114, which respectively correspond to the first to fourth color pixels SPXL11, SPXL12, SPXL21, SPXL22. The photoelectric converting part 211 (PD10) of the pixel array 210 is divided (segmented), by the first back-side separating part 214 and the second back-side separating part 215, into four rectangular regions, namely, the first photoelectric converting region (PD11) 2111, the second photoelectric converting region (PD12) 2112, the third photoelectric converting region (PD21) 2113 and the fourth photoelectric converting region (PD22) 2114.

The photoelectric converting part 211, which is divided (segmented) into the first photoelectric converting region (PD11) 2111, the second photoelectric converting region (PD12) 2112, the third photoelectric converting region (PD13) 2113 and the fourth photoelectric converting region (PD14) 2114, is buried in a semiconductor substrate 230 having a first substrate surface 231 and a second substrate surface 232 opposite to the first substrate surface 231, and is capable of photoelectrically converting received light and storing the resulting charges therein.

On top of the first photoelectric converting region (PD11) 2111, second photoelectric converting region (PD12) 2112, third photoelectric converting region (PD21) 2113, and fourth photoelectric converting region (PD22) 2114 of the photoelectric conversion section 211, the color filter part 212 is disposed on the first substrate surface 231 side (back side) via the oxide film (OXL) 213 that serves as a planar layer. On the second substrate surface 232 side (the front surface side) of the first photoelectric converting region (PD11) 2111, the second photoelectric converting region (PD12) 2112, the third photoelectric converting region (PD21) 2113 and the fourth photoelectric converting region (PD22) 2114, there are formed output parts OP11, OP12, OP21 and OP22 including, among others, an output transistor for outputting a signal determined by the charges produced by photoelectric conversion and stored.

The color filter part 212 is segmented into a green (G) filter region 2121, a red (R) filter region 2122, a blue (B) filter region 2123, and a green (G) filter region 2124, to form the respective color pixels. On the light incident side of the green (G) filter region 2121, the microlens (microprism) LNS221, one of the lens parts LNS220 of the lens part array 220, is disposed. On the light incident side of the red (R) filter region 2122, the microlens (microprism) LNS222, one of the lens parts LNS220 of the lens part array 220, is disposed. On the light incident side of the blue (B) filter region 2123, the microlens (microprism) LNS223, one of the lens parts LNS220 of the lens part array 220, is disposed. On the light incident side of the green (G) filter region 2124, the microlens (microprism) LNS224, one of the lens parts LNS220 of the lens part array 220, is disposed.

As described above, the photoelectric conversion part 211 (PD10), which is the rectangular region RCT20 defined by the four edges L11 to L14, is divided (segmented) by the first back side separating part 214 and the second back side separating part 215, into four rectangular regions, namely, the first photoelectric converting region (PD11) 2111, the second photoelectric converting region (PD12) 2112, the third photoelectric converting region (PD21) 2113 and the fourth photoelectric converting region (PD22) 2114. More specifically, the light incident portion of the photoelectric conversion part 211 (PD10) is divided into four portions by the back side separating part 214, which is basically positioned and shaped in the same manner as a back side metal (BSM).

A first separating part 2141 is formed at the boundary between the first photoelectric converting region 2111 of the first color pixel SPXL11 and the second photoelectric converting region 2112 of the second color pixel SPXL12. A third separating part 2142 is formed at the boundary between the third photoelectric converting region 2113 of the third color pixel SPXL22 and the fourth photoelectric converting region 2114 of the fourth color pixel SPXL22. A third separating part 2143 is formed at the boundary between the first photoelectric converting region 2111 of the first color pixel SPXL11 and the third photoelectric converting region 2113 of the third color pixel SPXL21. A fourth separating part 2144 is formed at the boundary between the second photoelectric converting region 2112 of the second color pixel SPXL12 and the fourth photoelectric converting region 2114 of the fourth color pixel SPXL22.

In the first embodiment, like typical back side metal BSM, the back side separating part 214 is basically formed at the boundaries between the color pixels SPXL11, SPXL12, SPXL21 and SPXL22 such that the back side separating part 214 protrudes from the oxide film 213 into the filter part 212.

In the photoelectric converting part PD10, the second back side separating part 215 may be formed as a trench-shaped back side separation, which is back side deep trench isolation (BDTI), such that the second back side separating part 260 is aligned with the back side separating part 214 in the depth direction of the photoelectric converting part 210 (the depth direction of the substrate 230: the Z direction).

As described above, the lens part array 220 includes one optical film FLM221 having predetermined optical function parts (for example, light condensing function) in a region where the lens parts LNS220 are to be formed, and the optical film FLM221 is formed in a single body to extend over a plurality of the lens parts LNS220 of the entire lens part array. The optical film FLM221 is made of an optical resin with a refractive index “n” of, for example, 1.5 to 1.6. The optical film is disposed over the entire pixel array 210 of the pixel part 20, and the microlenses (microprisms) LNS221, LNS222, LNS223, and LNS224 are integrally formed at positions corresponding to the photoelectric conversion parts (regions) 2111 (to 2114) arranged in the matrix pattern.

In the example illustrated in FIGS. 7 to 9, the microlens LNS221 of the lens part LNS220 is formed integrally with the optical film FLM221 as the optical function part that condenses the incident light onto one side (first substrate surface 231 side) of the correspondingly arranged photoelectric conversion part (region) 2111. The microlens LNS222 is formed integrally with the optical film FLM221 as the optical function part that condenses the incident light onto one side (first substrate surface 231 side) of the correspondingly arranged photoelectric conversion part (region) 2112. The microlens LNS223 is formed integrally with the optical film FLM221 as the optical function part that condenses the incident light onto one side (first substrate surface 231 side) of the correspondingly arranged photoelectric conversion part (region) 2113. The microlens LNS224 is formed integrally with the optical film FLM221 as the optical function part that condenses the incident light onto one side (first substrate surface 231 side) of the correspondingly arranged photoelectric conversion part (region) 2114.

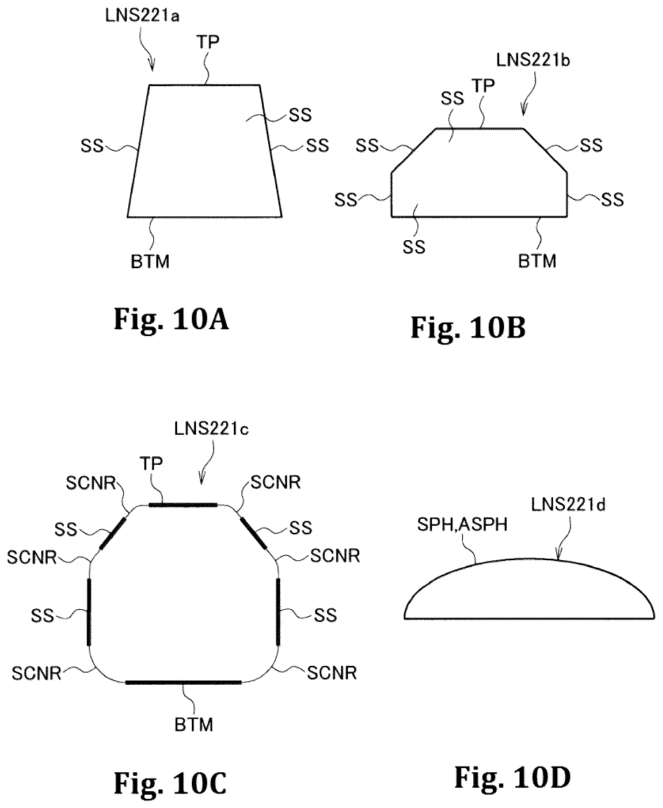

In the first embodiment, the microlenses (microprisms) LNS221 (to LNS224) are formed in a frustum (tetragonal frustum in this example) with the top TP facing the light incident side, as shown in FIG. 9. The frustum is not limited to the tetragonal frustum structure shown in FIGS. 7A to 9, but may be tetragonal frustum structures of another shape or pentagonal frustums or n-gonal frustum where n is greater than four, as shown in FIGS. 10A to 10D. A schematic configuration example of the tetragonal frustum microlenses LNS221 to LNS224 shown in FIGS. 7A to 9 is hereunder described.

The microlens LNS221 is a tetragonal frustum with a height of h11 between the bottom BTM11 and the top TP11 and with four side faces SS11, SS12, SS13, and SS14. In the example of FIGS. 7A to 9, the microlens LNS221 is formed as a right frustum with the top TP11 positioned right above the center of the photoelectric conversion part 2111 into which light is supposed to enter. Alternatively, the microlens LNS221 may be configured to have a structure in which the top TP11 is displaced from the position facing the center of the photoelectric conversion part 2111 into which light is supposed to enter and the light is guided to the surface of the photoelectric conversion part as a result of this displacement. In the first embodiment, the top TP11 is not a vertex but as a face region TP11 having a predetermined area. This face region TP11 has a plane parallel to one surface of the photoelectric conversion part (first substrate surface 231). The face region TP11 can adjust its parallelism depending on the pixel position. In the vicinity of the center of the pixel array, the irradiated light beam (incident light beam) enters the face region TP111 and the side faces SS11, SS12, SS13, SS14 at a predetermined angle with the normal to the substrate 230, including almost vertical (normal direction to the substrate 230), as shown in FIGS. 7A to 7C and 9. Whereas in the periphery of the pixel array, irradiated light beam (incident light beam) enters the face regions and side faces at a predetermined angle with the normal to the substrate 230, including a principal ray angle that is displaced from the vertical depending on the CRA of the lens. The light beam that entered the microlens LNS221 is propagated through the lens and condenses at the focal point FP defined at the center of the photoelectric conversion part 2111. Alternatively, the light beam that entered the microlens LNS221 is propagated through the lens and is not condensed on the focal point FP defined at the center of photoelectric conversion part 2111, but is guided to any position on a surface side of photoelectric conversion part 2111. The top TP11 may be a vertex without a surface area.

The microlens LNS222 is a tetragonal frustum with a height of h21 between the bottom BTM21 and the top TP21 and with four side faces SS21, SS22, SS23, and SS24. In the example of FIGS. 7A to 9, the microlens LNS222 is formed as a right frustum with the top TP21 positioned right above the center of the photoelectric conversion part 2112 into which light is supposed to enter. Alternatively, the microlens LNS222 may be configured to have a structure in which the top TP21 is displaced from the position facing the center of the photoelectric conversion part 2112 into which light is supposed to enter and the light is guided to the surface of the photoelectric conversion part as a result of this displacement. In the first embodiment, the top TP21 is not a vertex but as the face region TP211 having a predetermined area. This face region TP21 has a plane parallel to one surface of the photoelectric conversion part (first substrate surface 231). The face region TP21 can adjust its parallelism depending on the pixel position. In the vicinity of the center of the pixel array, the irradiated light beam (incident light beam) enters the face region TP211 and the side faces SS21, SS22, SS23, SS24 at a predetermined angle with the normal to the substrate 230, including almost vertical (normal direction to the substrate 230), as shown in FIGS. 7A to 7C and 9. Whereas in the periphery of the pixel array, irradiated light beam (incident light beam) enters the face regions and side faces at a predetermined angle with the normal to the substrate 230, including a principal ray angle that is displaced from the vertical depending on the CRA of the lens. The light beam incident on the microlens LNS222 is propagated through the lens and condensed at the focal point FP defined at the center of the photoelectric conversion part 2112. Alternatively, the light beam that entered the microlens LNS222 is propagated through the lens and is not focused on the focal point FP defined at the center of photoelectric conversion part 2112, but is guided to any position on a surface side of photoelectric conversion part 2112. The top TP21 may be a vertex without a surface area.

The microlens LNS223 is a tetragonal frustum with a height of h31 between the bottom BTM31 and the top TP31 and with four side faces SS31, SS32, SS33, and SS34. In the example of FIGS. 7A to 9, the microlens LNS223 is formed as a right frustum with the top TP31 positioned right above the center of the photoelectric conversion part 2113 into which light is supposed to enter. Alternatively, the microlens LNS223 may be configured to have a structure in which the top TP31 is displaced from the position facing the center of the photoelectric conversion part 2113 into which light is supposed to enter and the light is guided to the surface of the photoelectric conversion part as a result of this displacement. In the first embodiment, the top TP31 is not a vertex but as the face region TP31 having a predetermined area. This face region TP311 has a plane parallel to one surface of the photoelectric conversion part (first substrate surface 231). The face region TP31 can adjust its parallelism depending on the pixel position. In the vicinity of the center of the pixel array, the irradiated light beam (incident light beam) enters the face region TP311 and the side faces SS31, SS32, SS33, SS34 at a predetermined angle with the normal to the substrate 230, including almost vertical (normal direction to the substrate 230), as shown in FIGS. 7A to 7C and 9. Whereas in the periphery of the pixel array, irradiated light beam (incident light beam) enters the face regions and side faces at a predetermined angle with the normal to the substrate 230, including a principal ray angle that is displaced from the vertical depending on the CRA of the lens. The light beam that entered the microlens LNS223 is propagated through the lens and condensed at the focal point FP defined at the center of the photoelectric conversion part 2113. Alternatively, the light beam that entered the microlens LNS223 is propagated through the lens and is not condensed at the focal point FP defined at the center of photoelectric conversion part 2113, but is guided to any position on a surface side of photoelectric conversion part 2113. The top TP31 may be a vertex without a surface area.

The microlens LNS224 is a tetragonal frustum with a height of h41 between the bottom BTM41 and the top TP41 and with four side faces SS41, SS42, SS43, and SS44. In the example of FIGS. 7A to 9, the microlens LNS224 is formed as a right frustum with the top TP41 positioned right above the center of the photoelectric conversion part 2114 into which light is supposed to enter. Alternatively, the microlens LNS224 may be configured to have a structure in which the top TP41 is displaced from the position facing the center of the photoelectric conversion part 2114 into which light is supposed to enter and the light is guided to the surface of the photoelectric conversion part as a result of this displacement. In the first embodiment, the top TP41 is not a vertex but as the face region TP411 having a predetermined area. This face region TP41 has a plane parallel to one surface of the photoelectric conversion part (first substrate surface 231). The face region TP41 can adjust its parallelism depending on the pixel position. In the vicinity of the center of the pixel array, the irradiated light beam (incident light beam) enters the face region TP411 and the side faces SS41, SS42, SS43, SS44 at a predetermined angle with the normal to the substrate 230, including almost vertical (normal direction to the substrate 230), as shown in FIGS. 7A to 7C and 9. Whereas in the periphery of the pixel array, irradiated light beam (incident light beam) enters the face regions and side faces at a predetermined angle with the normal to the substrate 230, including a principal ray angle that is displaced from the vertical depending on the CRA of the lens. The light beam that entered the microlens LNS224 is propagated through the lens and focused on the focal point FP defined at the center of the photoelectric conversion part 2114. Alternatively, the light beam that entered the microlens LNS224 is propagated through the lens and is not condensed at the focal point FP defined at the center of photoelectric conversion part 2114, but is guided to any position on a surface side of photoelectric conversion part 2114. The top TP41 may be a vertex with no surface area.

Depending on the positions of the photoelectric conversion parts 2111 to 2114 of the pixel array 210 that are arranged corresponding to the microlenses LNS221 to LNS24, the angles of the vertexes (tops) to the substrate 230 and the four side faces SS11 to SS14, SS21 to SS24, SS31 to SS34, SS41 to SS44, and the lengths of the sides of the face regions TP11 to T41 of the microlenses LNS221 to LNS24 are adjusted. In the first embodiment, the microlenses LNS221 to LNS24 are basically formed such that, suppose an incident light beam having a spatially uniform intensity distribution, a first incident light amount mainly incident from a first direction (X direction) of the pixel array and a second incident light amount mainly incident from a second direction (Y direction) become substantially equal.

FIGS. 10A to 10D illustrate other schematic configurations of the lens part in the pixel part relating to the first embodiment of the invention. FIG. 10A shows an example of a microlens (microprism) LNS221a with a tetragonal frustum structure, which has a larger face area at the top TP and a greater height than those of the example of FIG. 9. FIG. 10B shows an example of a microlens (microprism) LNS221b with an octagonal frustum structure. FIG. 10C shows an example of a microlens (microprism) LNS221c with an octagonal frustum structure having smooth corners SCNR. FIG. 10D shows an example of a microlens (microprism) LNS221d with a spherical surface SPH or aspheric surface ASPH, the ultimate frustum structure.

The individual elements of the film-integrated (film-integrally formed) microlenses (microprisms) LNS221 (to LNS24) that are integrally formed with the optical film FLM221 in the first embodiment can have various shapes, such as the shapes shown in FIGS. 7A to 9 and 10A to 10D. In other words, the shape of the individual microlenses (microprisms) LNS221 (to LNS24) is not limited by the shapes shown in FIGS. 7A to 10D. Each microlens (microprism) integrally formed with the optical film FLM221 is designed by calculating the shape and size to obtain the desired shape, size, and distance of the focal point. Design variables include the number of faces, shape, width, and angles between the various faces. Individual microlenses (microprisms) may have more surfaces than those shown in FIGS. 10A to 10D.

Conventional microlens arrays used in CIS pixels are subject to a lens shading effect. Shading is caused by converging behavior of microlenses at a large Chief Ray Angle (CRA). To improve the shading effect, the position of the microlens is shifted depending on the CRA from the center toward the edge of the pixel plane. As discussed above, this is known as microlens shift. In the case of individual microlenses (microprisms) that are integrally formed with the optical film FLM221, uniformity of illumination at the sensor surface can be ensured by slightly modifying the shape and angle of the light incidence and propagation paths of the microlenses.

In this first embodiment, the microlens array as the film-integrated optical element array is preferably formed of microlenses 221d that each have an aspherical surface ASPH whose shape varies depending on the position of the corresponding pixel in the pixel array, as shown in FIG. 10D.

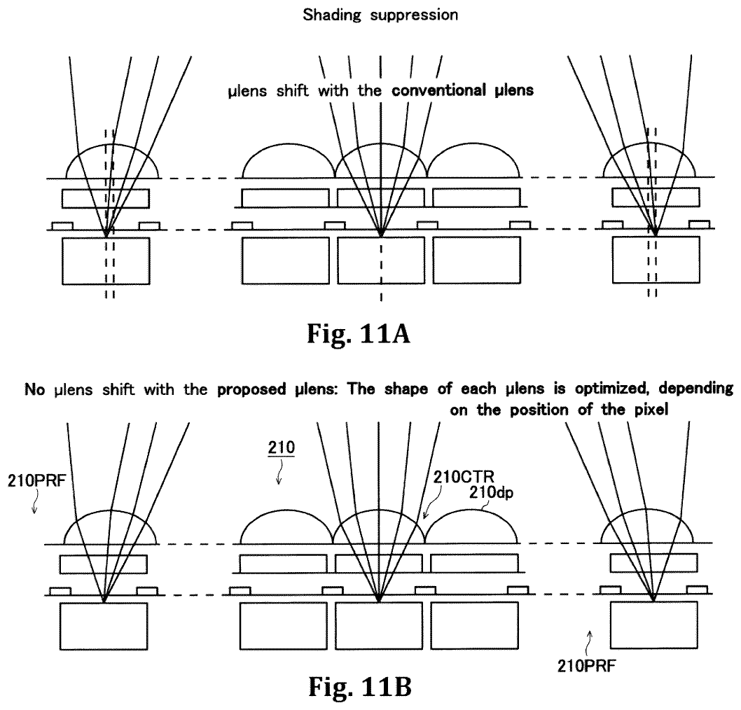

FIGS. 11A and 11B illustrates comparison of a shading suppression effect between the pixel array of the first embodiment of the invention and a pixel array of a comparative example. FIG. 11A illustrates the shading suppression effect of a comparative example in which the microlens shift is applied. FIG. 11B illustrates the shading suppression effect of the first embodiment in which the microlens shift is not applied but the shape of each microlens varies depending on the position of the corresponding pixel in the pixel array.

In the comparative example, microlenses 221dc can only be manufactured in the same shape regardless of the positions of the pixels in the pixel array 210 due to the manufacturing process, and this causes shading at the periphery of the pixel array (because the amount of light incident into the pixels is reduced at the periphery of the pixel array). The microlens shift is commonly employed as a method to solve this problem, but it has not been able to completely eliminate the shading.

Whereas in the solid-state imaging device 10 of the first embodiment, the shapes of microlenses 221dp are changed depending on the position of the corresponding pixel in the pixel array. Specifically, as shown in FIG. 11B, in a central region 210CTR of the pixel array 210, the degree of deformation of the aspherical surface of the microlens 221dp deviated from the spherical surface SPH is reduced. And in a peripheral region 210PRF of the pixel array 210, the degree of deformation of the aspherical surface ASPH of microlens 221dp deviated from the spherical surface SPH is increased. Furthermore, the degree of deformation is optimized for each individual microlens 221dp. Therefore, in the solid-state imaging device 10 of the first embodiment, it is possible to suppress shading more precisely than in the comparative example in which the microlens shift is applied.

In this first embodiment, the lens part array 220 is formed of an array of multiple microlenses (microprisms) that are computationally designed using a PC or the like and fabricated onto a roll film using a laser or the like. For example, instead of shifting the microlens array depending on the position of the photoelectric conversion part (pixel) in the pixel array, the angle of each microlens is computationally designed. The microlens array is disposed on the photoelectric conversion part (pixel) array. This provides a more uniform response over the pixel array.

The fabrication of the microlenses LNS221 to LNS224 on the optical film FLM221 is not limited to a method using laser lithography technique as described here, but can also be fabricated by creating a mold and transferring it to a roll film.

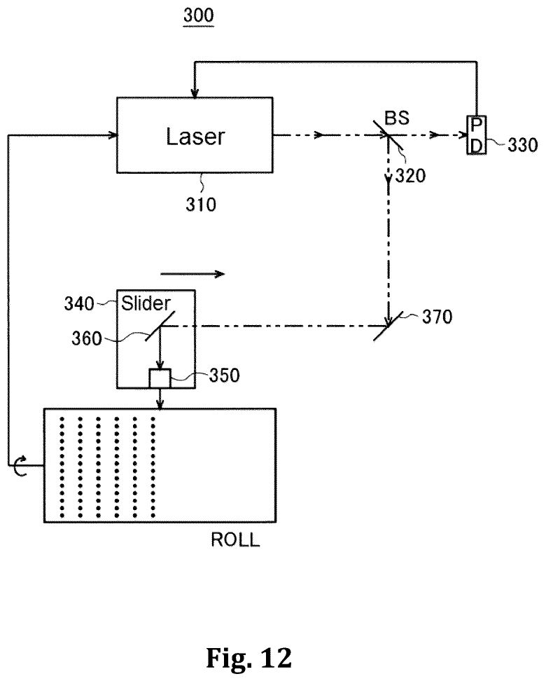

FIG. 12 is an example of an apparatus for manufacturing the lens part array 220 relating to the first embodiment of the invention.

A lens part array manufacturing apparatus 300 relating to the embodiment of FIG. 12 includes a laser 310, a beam splitter (BS) 320, a photodetector (PD) 330 for controlling the laser beam, a slider 340, a focus controllable optical head 350 mounted on the slider 340, and mirrors (MR) 360, 370 for forming an optical path of the laser beam to the optical head 350. The manufacturing apparatus 300 can fabricate the lens part array 220 with good controllability and high precision.

The optical film FLM221 of the lens part array 220 is bonded to the light incident side of the pixel array 210 to form the pixel part 20.

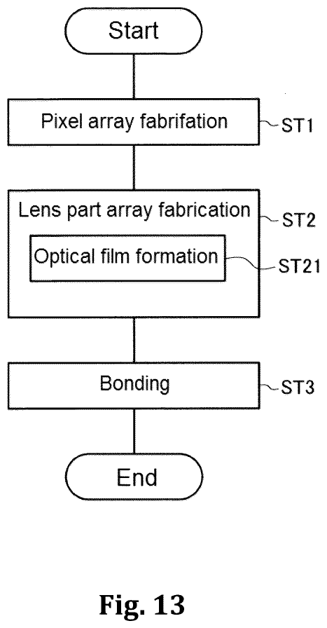

FIG. 13 schematically illustrates a manufacturing method of the pixel part of the solid-state imaging device relating to the first embodiment of the invention.

The pixel part 20 including the pixel array 210 and lens part array 220 is fabricated through a pixel array formation step ST1, a lens part array formation step ST2 including an optical film formation step ST21, and a bonding step ST3, as shown in FIG. 13. As an example, the pixel array formation process ST1 and the lens section array formation process ST2 including the optical film formation process ST21 are shown here as serial processes, but the invention is not limited to this example and the two steps may be performed in parallel.

In the pixel array formation step ST1, pixels each of which includes the plurality of photoelectric conversion parts 2111-2114 that photoelectrically convert light of a predetermined wavelength incident from one side are formed in an array. Here, an example of forming an array of pixels each of which includes the four (plurality) photoelectric conversion parts 2111-2114 will be now described according to the configuration of the embodiment. However, each pixel may include any number of photoelectric conversion parts, and the invention is not limited to four.

In the lens part array formation step ST2, an array of the plurality of lens parts LNS221 to LNS224 is formed corresponding to one side of the photoelectric conversion parts 2111 to 2114, respectively, of the pixel array 210. In this way, formed is the lens part array 220 including the plurality of lens parts LNS221 to LNS224 that condense the incident light onto the photoelectric conversion parts 2111 to 2114, respectively, to cause the light to enter the photoelectric conversion part from one side of the corresponding photoelectric conversion part. The lens part array formation step ST2 includes the film formation step ST21. In the film formation process ST21, the single optical film FLM221 is formed in a single body to extend over the plurality of lens parts of the entire array. The optical film has predetermined optical functional parts, for example, a light condensing function, in the region where the lens parts are to be formed.

In the bonding step ST3, the optical film FLM221 of the lens part array 220 is bonded to the light incident side of the pixel array 210 to form the pixel part 20.

As described above, in the first embodiment, the pixel part 20 includes a pixel array 210 in which the plurality of photoelectric conversion parts 2111, 2112, 2113, 2114 that photoelectrically convert light of a predetermined wavelength incident from one side are arranged in an array, and a lens part array 220 including a plurality of lens parts LNS220 (LNS221 to LNS224) arranged in an array. The lens parts are disposed corresponding to the one side of the corresponding photoelectric conversion parts 2111 (to 2114) of the pixel array 210. The lens parts LNS220 condense incident light onto the correspondingly arranged photoelectric conversion parts 2111 (to 2114) to cause the light to enter the photoelectric conversion part from the one side of the corresponding photoelectric conversion parts. The pixel part 20 is bonded to the lens part array 220 are bonded and stacked to each other in the Z direction. In the first embodiment, the lens part array 220 in which the lens parts LNS220 are integrally formed on the optical film FLM221, which is a roll film, is bonded to the light incident side of the pixel array 210.

In the first embodiment, the lens part array 220 includes one optical film FLM221 having predetermined optical function parts (for example, light condensing function) in a region where the lens parts LNS220 are to be formed, and the optical film FLM221 is formed in a single body to extend over a plurality of the lens parts LNS220 of the entire lens part array 220. In the first embodiment, the lens parts LNS220 include the microlenses (microprisms) LNS221, LNS222, LNS223, and LNS224 that are integrally formed with the first optical film FLM221 as the optical function parts that condense incident light onto the correspondingly arranged photoelectric conversion parts 2111 (to 2114) to let the light enter from one side (first substrate side 231) of the photoelectric conversion parts. In the first embodiment, the microlenses LNS221 (to LNS224) are formed in a frustum or aspheric shape including the one shown in FIG. 10D with the top facing the light incident side.

According to the first embodiment, there are not many constraint conditions on the optical structure and characteristics imposed when the lens parts are formed as the microlenses. As a result, according to the first embodiment, it is possible to manufacture the lens part array 220 without complicated work, which in turn has the advantage of making the manufacture of the pixel part 20 easily. It also makes it possible to reduce the thickness of the substrate underneath the microlenses, thereby reducing crosstalk between adjacent pixels. In addition, by using the optical component array in a sheet form, it is possible to control more precisely than the conventional method of manufacturing microlens arrays and thereby images without shading can be obtained, which results in an improved performance.

According to the first embodiment, the shapes of the microlenses can be easily modified depending on the position where the microlens is situated. In this way, it is possible to more appropriately compensate the performance degradation in the edge regions of the image plane occurred at large CRAs, which in turn makes it possible to suppress shading accurately.

### Second Embodiment

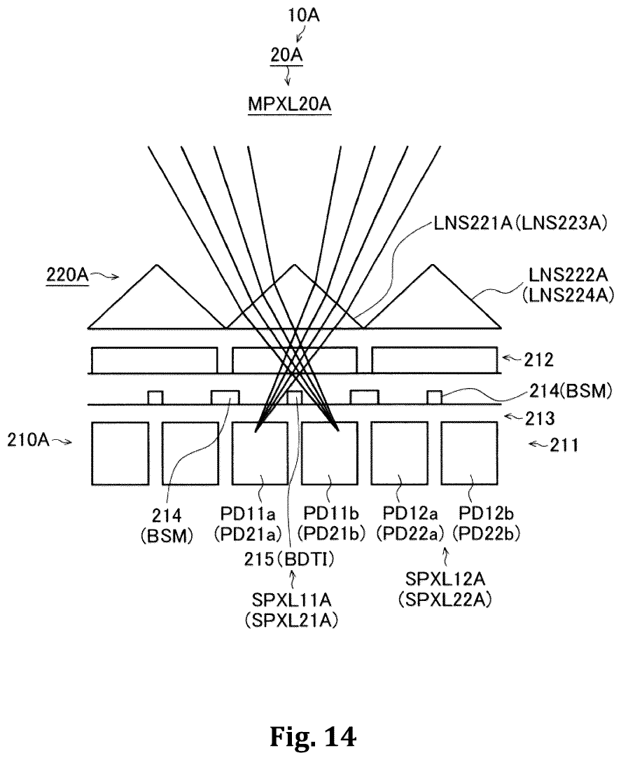

FIG. 14 schematically illustrates a configuration of the lens part in the pixel part of a solid-state imaging device (CMOS image sensor) relating to a second embodiment of the invention.

The second embodiment differs from the first embodiment in the following points. In the first embodiment, the lens part 220 of the multi-pixel MPXL20 includes the microlenses LNS221 to LNS224 through which rays of incident light enter the photoelectric conversion parts PD11, PD12, PD21, PD22 of the four color pixels SPXL11, SPXL12, SPXL21, SPXL22, respectively.

Whereas in a multi-pixel MPXL20A of this second embodiment, the first photoelectric conversion part PD11 of the first color pixel SPXL11A is divided (segmented) into two regions PD11a and PD11b by the separating part 214 (215), and the single microlens LNS221A causes the light to incident onto the two areas PD11a and PD11b and thereby making it possible to obtain the PDAF information. Similarly, the first photoelectric conversion part PD12 of the second color pixel SPXL12A is divided (segmented) into two regions PD12a and PD12b by the separating part 214 (215), and the single microlens LNS222A causes the light to incident onto the two regions PD12a and PD12b and thereby making it possible to obtain the PDAF information.

Similarly, the first photoelectric conversion part PD21 of the third color pixel SPXL21A is divided (segmented) into two regions PD21a and PD21b by the separating part 214 (215), and the single microlens LNS223A causes the light to incident onto the two regions PD21a and PD21b and thereby making it possible to obtain the PDAF information. Similarly, the first photoelectric conversion part PD22 of the fourth color pixel SPXL22A is divided (segmented) into two regions PD22a and PD22b by the separating part 214 (215), and the single microlens LNS224A causes the light to incident onto the two regions PD22a and PD22b and thereby making it possible to obtain the PDAF information.

In the second embodiment, the tops of the microlenses LNS221A to LNS224A are formed as vertexes with no surface area, so that rays of light can efficiently enter the two narrow regions.

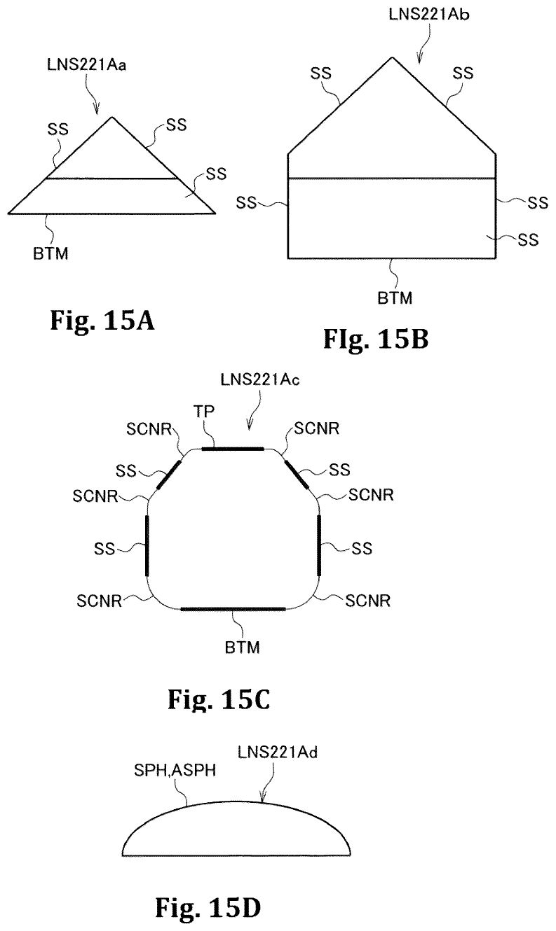

FIGS. 15A to 15C illustrate other schematic configurations of the lens part in the pixel part relating to the second embodiment of the invention. FIG. 15A shows an example of a microlens (microprism) LNS221Aa with a tetragonal frustum structure, which has a larger face area at the top TP and a greater height than those of the example of FIG. 14. FIG. 15B shows an example of a microlens (microprism) LNS221Ab with an octagonal frustum structure. FIG. 15C shows an example of a microlens (microprism) LNS221Ac with an octagonal frustum structure having smooth corners SCNR. FIG. 15D shows an example of a microlens (microprism) LNS221Ad with a spherical surface SPH or aspheric surface ASPH, the ultimate frustum structure.

The individual elements of the film-integrated (film-integrally formed) microlenses (microprisms) LNS221 (to LNS24) that are integrally formed with the optical film FLM221 in the second embodiment can have various shapes, such as the shapes shown in FIGS. 14 and 15A to 15D. In other words, the shape of the individual microlenses is not limited by the shapes shown in FIGS. 14 to 15D. Each microlens (microprism) integrally formed with the optical film FLM221 is designed by calculating the shape and size to obtain the desired shape, size, and distance of the focal point. Design variables include the number of faces, shape, width, and angles between the various faces. Each microprism may have more surfaces than those shown in FIGS. 15A to 15D.

According to the second embodiment, similarly to the above described advantageous effects of the first embodiment, it is possible to manufacture the lens part array 220A without complicated work, which in turn has the advantage of making the manufacture of the pixel part 20A easily. It also makes it possible to reduce the thickness of the substrate underneath the microlenses, thereby reducing crosstalk between adjacent pixels. In addition, by using the optical component array in a sheet form, it is possible to control more precisely than the conventional method of manufacturing microlens arrays and thereby images without shading can be obtained, which results in an improved performance.

According to the second embodiment, the shapes of the microlenses (microprisms in the first embodiment) can be easily modified depending on the position where the microlens is situated. In this way, it is possible to more appropriately compensate the performance degradation in the edge regions of the image plane occurred at large CRAs. Furthermore, it is possible to realize the PDAF function with the configuration in which the pixels sharing a single microlens.

### Third Embodiment

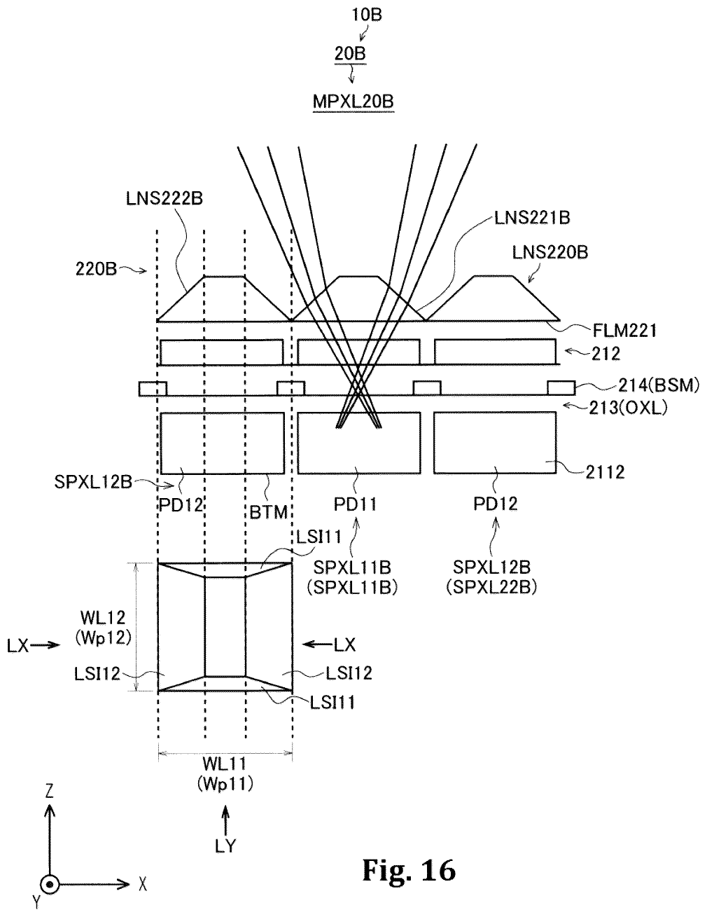

FIG. 16 schematically illustrates a configuration of the lens part in the pixel part of a solid-state imaging device (CMOS image sensor) relating to a third embodiment of the invention.

An exemplary microlens relating to the third embodiment differs from that of the first embodiment in the following points.

In the first embodiment, the lens part 220 of the multi-pixel MPXL20 includes the microlenses LNS221 to LNS224 each of which is formed in a substantially square shape and through which rays of incident light enter the photoelectric conversion parts PD11, PD12, PD21, PD22 of the four color pixels SPXL11, SPXL12, SPXL21, SPXL22, respectively. The microlenses LNS221 to LNS224, each of which is formed in a substantially square shape, allows substantially the equal amount of light from all directions of a first direction (in this example, the X direction of the Cartesian coordinate system) side, which corresponds to the horizontal direction of the pixel array, and a second direction (in this example, the Y direction) side, which is orthogonal to the first direction (X direction) to enter the corresponding photoelectric conversion parts PD11, PD12, PD21, and PD22. Specifically, for an incident light beam having a spatially uniform intensity distribution, the microlenses LNS221 to LNS224 are formed such that a first incident light amount LX incident from the first direction and a second incident light amount LY incident from the second direction become substantially equal.

Whereas in the multipixel MPXL20B of the third embodiment of the invention, for an incident light beam having a spatially uniform intensity distribution and entering the corresponding photoelectric conversion parts PD11, PD12, the microlenses LNS221B to LNS224B are formed such that the first incident light amount LX incident from the first direction X differs from the second incident light amount LY incident from the second direction Y. FIG. 16 shows an example of the microlenses LNS221B (to LNS224B) configured such that, for an incident light beam having a spatially uniform intensity distribution and entering the corresponding photoelectric conversion parts PD11, PD12, PD21, and PD22, the first incident light amount LX incident from the first direction X is larger than the second incident light amount LY incident from the second direction Y. In other words, at the microlenses LNS221B to LNS224B, a larger amount of the light LX from the first direction X is incident on the photoelectric conversion parts PD11, PD12, PD21, and PD22 than the light LY from the second direction Y, for the incident light beam having a spatially uniform intensity distribution.

One configuration example of the microlenses LNS221B to LNS224B in the third embodiment will be now described with reference to FIG. 16.

In the multi-pixel MPXL20B of the third embodiment, the microlenses LNS221B to LNS224B are each formed in an rectangular parallelepiped shape, and a length (width) WL11 of a first light-incident surface LSI11 in the first direction (in the X direction of the Cartesian coordinate system in this example) corresponding to the horizontal direction of the pixel array is longer than a length (width) WL12 of a second light-incident surface LSI12 in the second direction (in the Y direction in this example) orthogonal to the first direction (X direction). For example, the color pixels SPXL11B, SPXL12B, SPXL21B, and SPXL22B including the photoelectric conversion parts PD11, PD12, PD21, and PD22, respectively are each formed such that a width WP12 in the second direction Y orthogonal to the first direction X is larger than the width WP11 in the first direction X.

In the microlenses LNS221B to LNS224B having such a configuration, mainly rays of light in the first direction X are incident through the second light incident surface LSI12 on the photoelectric conversion parts PD11, PD12, PD21, and PD22. In other words, in the microlenses LNS221B to LNS224B, a larger amount of light LX in the first direction X enters through the second light incident surface LSI12 than light LY entering through the first light incident surface LSI11.

In the third embodiment, the amount of the first incident light LX from the first direction X can be adjusted (minor adjusted) by the shape of the second light incident surface LSI 12, such as the area or the angle between the second light incident surface LSI 12 and the bottom surface BTM. Similarly, the amount of the second incident light LY from the second direction Y can be adjusted (minor-adjusted) by the shape of the first light incident surface LSI 11, for example, the area and the angle between the first light incident surface LSI 11 and the bottom surface BTM.

Note that the first direction is the X direction (horizontal direction) and the second direction is the Y direction (vertical direction) in the above embodiments, however the first direction may be the Y direction (vertical direction) and the second direction may be the X direction (horizontal direction).

According to the third embodiment, similarly to the above described advantageous effects of the first embodiment, it is possible to manufacture the lens part array 220B without complicated work, which in turn has the advantage of making the manufacture of the pixel part 20 easily. It also makes it possible to reduce the thickness of the substrate underneath the microlenses, thereby reducing crosstalk between adjacent pixels. In addition, by using the optical component array in a sheet form, it is possible to control more precisely than the conventional method of manufacturing microlens arrays and thereby images without shading can be obtained, which results in an improved performance. Furthermore, it is possible to realize the PDAF function with the configuration in which the pixels sharing a single microlens.

According to the third embodiment, the shapes of the microlenses (microprisms in the first embodiment) can be easily modified depending on the position where the microlens is situated. In this way, it is possible to more appropriately compensate the performance degradation in the edge regions of the image plane occurred at large CRAs.

### Fourth Embodiment

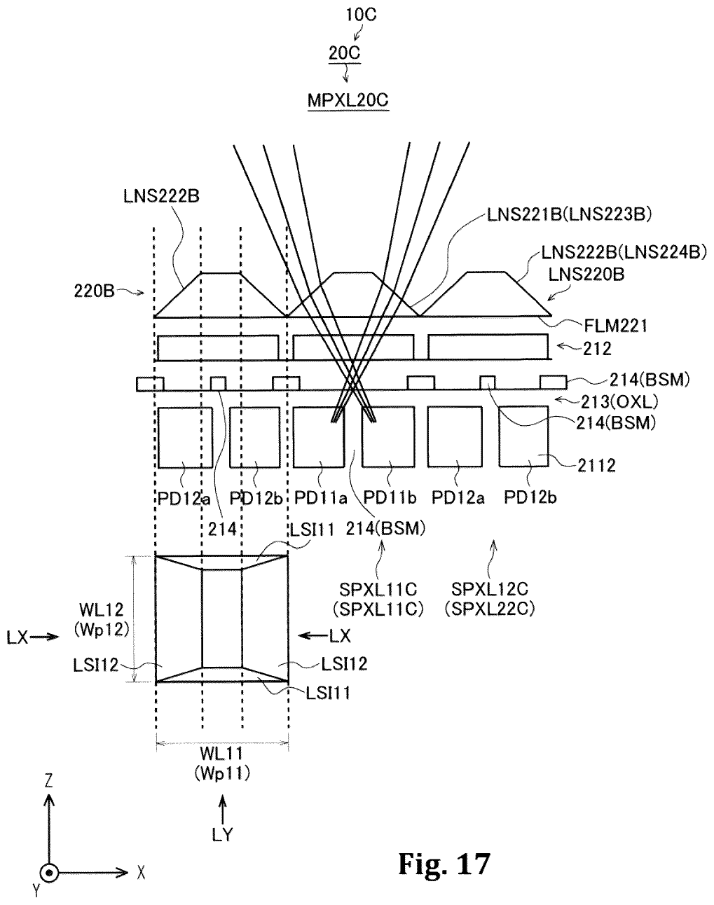

FIG. 17 schematically illustrates a configuration of the lens part in the pixel part of a solid-state imaging device (CMOS image sensor) relating to a fourth embodiment of the invention.

The fourth embodiment differs from the third embodiment in the following points. In the third embodiment, the lens part 220B of the multi-pixel MPXL20B includes the microlenses LNS221B to LNS224B through which rays of incident light enter the photoelectric conversion parts PD11, PD12, PD21, PD22 of the four color pixels SPXL11, SPXL12, SPXL21, SPXL22, respectively.

Whereas in a multi-pixel MPXL20C of this fourth embodiment, the first photoelectric conversion part PD11 of the first color pixel SPXL11C is divided (segmented) into two regions PD11a and PD11b by the separating part 214 (215), and the single microlens LNS221B causes the light to incident onto the two areas PD11a and PD11b and thereby making it possible to obtain the PDAF information. Similarly, the first photoelectric conversion part PD12 of the second color pixel SPXL12C is divided (segmented) into two regions PD12a and PD12b by the separating part 214 (215), and the single microlens LNS222B causes the light to incident onto the two regions PD12a and PD12b and thereby making it possible to obtain the PDAF information.

Similarly, the first photoelectric conversion part PD21 of the third color pixel SPXL21C and the first photoelectric conversion part PD21 of the fourth color pixel SPXL22C is divided (segmented) into two regions by the separating part 214 (215), and the single microlens LNS224B, LNS224B respectively causes the light to incident onto the two regions and thereby making it possible to obtain the PDAF information.

In the fourth embodiment, the tops of the microlenses LNS221B to LNS224B are formed as vertexes with a surface area, so that a large amount of light can efficiently enter the two narrow regions mainly from the first direction X. Specifically, the microlenses LNS221B to LNS224B of the fourth embodiment are configured to receive a large fraction of the light LX from the X side in the first direction and a small fraction of the light LY from the Y side in the second direction or not receive the light LY from the Y side so that only the optical information in the first direction (here, the X direction) can be used and the optical information in the second direction (here, the Y direction) can be unused or used as offset information.

In the fourth embodiment, the amount of the first incident light LX from the first direction X can be adjusted (minor adjusted) by the area of the second light incident surface LSI 12 or the angle between the second light incident surface LSI 12 and the bottom surface BTM. Similarly, the amount of the second incident light LY from the second direction Y can be adjusted (minor-adjusted) by area of the first light incident surface LSI 11 or the angle between the first light incident surface LSI 11 and the bottom surface BTM. In this case, the angle between the first light incident surface LSI 11 and the bottom surface BTM is about 80 to 90 degrees. This significantly suppresses the incidence of the light LY comes from above in the second direction Y onto the first light incident surface LSI11.

In the microlenses LNS221B to LNS224B having such a configuration, mainly rays of light in the first direction X are incident through the second light incident surface LSI12 on the photoelectric conversion parts PD11a, PD11b, PD11a, and PD12b (PD21a, PD21b, PD22a, and PD22). In other words, in the microlenses LNS221B to LNS224B, a larger amount of light with directionality in the first direction X enters through the second light incident surface LSI12 than the light entering through the first light incident surface LSI11.

As described above, in the fourth embodiment, it is possible to employ only the optical information in the first direction (here, the X direction) and the optical information in the second direction (here, the Y direction) is unused or used as the offset information, making it possible to improve the accuracy of the PDAF function, for example.

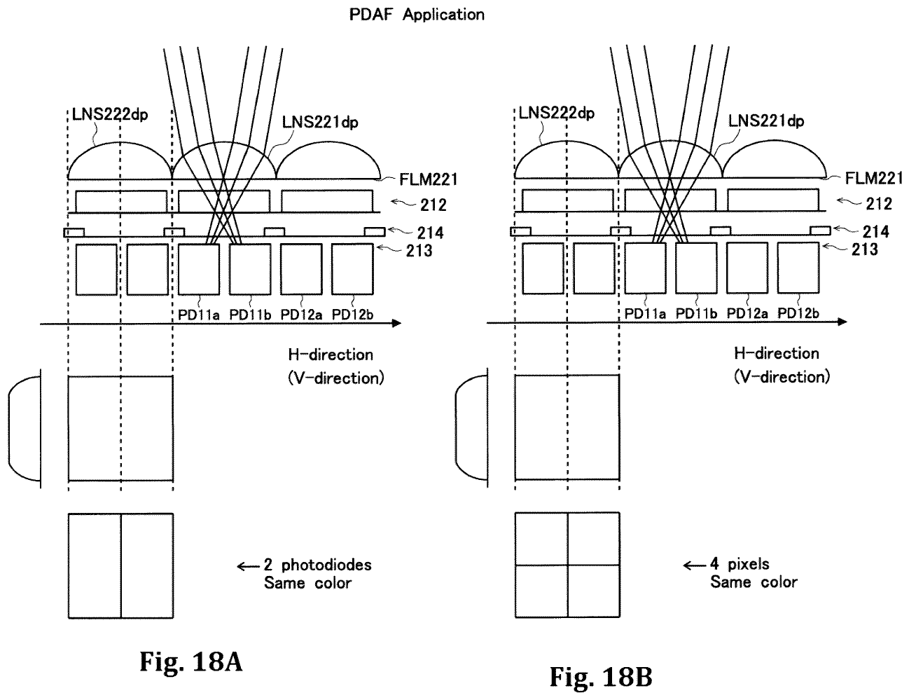

The following describes an application example of the solid-state imaging device 10 relating to the fourth embodiment. FIGS. 18A and 18B illustrate the application example of the solid-state imaging device relating to the fourth embodiment of the invention. FIG. 18A shows a first application example of the solid-state imaging device relating to the fourth embodiment of the invention, and FIG. 18B shows a second application example of the solid-state imaging device relating to the fourth embodiment of the invention.

In the solid-state imaging devices (CMOS image sensors), in order to prevent the decline in the sensitivity and dynamic range due to the reduced pixel pitch while maintaining high resolution with multi-pixels, for example, two or four pixels of the same color are arranged adjacent to each other. When resolution is pursued, pixel signals are read out from the pixels, and when resolution and dynamic range performance are required, the signals of pixels of the same color may be added and read out. In such a CMOS image sensor, a single microlens is shared by the two, four or more adjacent pixels of the same color.

FIGS. 18A and 18B show two application examples in which a single microlens is shared by multiple same-color pixels in the pixel array. FIG. 18A shows the application example where one microlens LNS221C (to LNS224C) is shared by two same-color pixels (photodiode PDs). FIG. 18B shows the application example where one microlens LNS221C (to LNS224C) is shared by four same-color pixels (photodiode PDs).

According to the fourth embodiment, similarly to the above described advantageous effects of the first and third embodiments, it is possible to manufacture the lens part array 220 without complicated work, which in turn has the advantage of making the manufacture of the pixel part 20 easily. It also makes it possible to reduce the thickness of the substrate underneath the microlenses, thereby reducing crosstalk between adjacent pixels. In addition, by using the optical component array in a sheet form, it is possible to control more precisely than the conventional method of manufacturing microlens arrays and thereby images without shading can be obtained, which results in an improved performance. Furthermore, it is possible to realize the PDAF function with the configuration in which the pixels sharing a single microlens.

According to the fourth embodiment, the shapes of the microlenses (microprisms in the fourth embodiment) can be easily modified depending on the position where the microlens is situated. In this way, it is possible to more appropriately compensate the performance degradation in the edge regions of the image plane occurred at large CRAs.

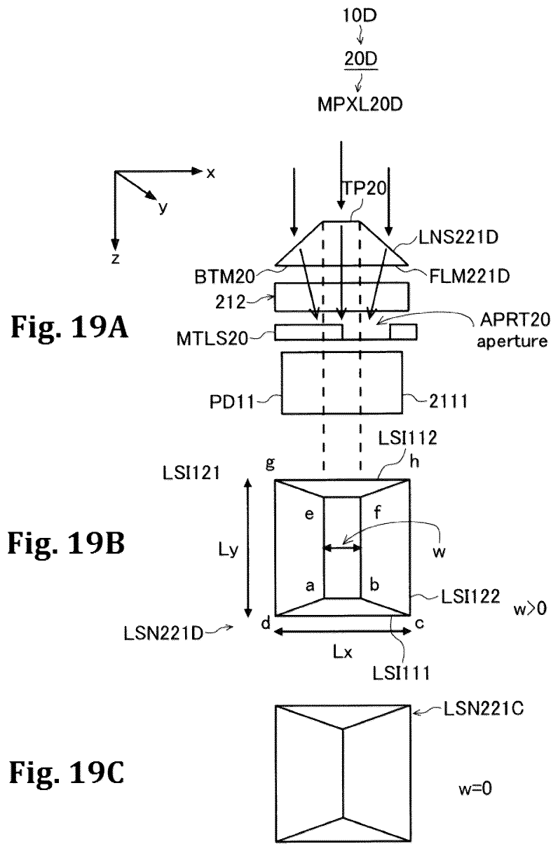

Fifth Embodiment FIGS. 19A to 19C schematically illustrate the configuration of the lens part in the pixel part of the solid-state imaging device (CMOS image sensor) relating to the fifth embodiment of the invention. FIG. 19A shows a schematic view of the lens part, FIG. 19B shows a top view of a microlens whose top TP has a predetermined width, and FIG. 19C shows a top view of a microlens whose top TP has a predetermined width.

In FIGS. 19A to 19C, for ease of understanding, the same components as those of FIGS. 16 and 17 are given the same reference numerals.

The fifth embodiment differs from the fourth embodiment in the following points. In the fourth embodiment, the photoelectric conversion part (photodiode (PD)) in the pixel is divided into two (two provided) instead of using the light shielding film. This configuration is for realizing a method (pupil division method) for detecting a phase differences based on the amount of phase shift between signals obtained through a pair of photoelectric conversion parts (photodiodes).

Whereas, in the fifth embodiment, for example, half of one photoelectric converting region PD (light-receiving region) is shielded by the light-shielding film. This configuration realizes the image-plane phase detection method in which a phase difference on the image is detected using the phase detection pixel that receives light in a right half and the phase detection pixel that receive light in a left half.

In the image-plane phase detection method using the light-shielding film, a rectangular-shaped metal shield MTLS20 shading an approximately half of the area of the light-receiving region of the photoelectric converting region PD and a rectangular-shaped aperture APRT20 exposing the remaining half of the light-receiving region of the photoelectric converting region PD are formed on the incident surface (first surface of the substrate) of the photoelectric converting region PD. The metal shield MTLS20 is provided and embedded by changing the width of the backside metal BSM. This ensures an angular response providing the responsiveness commensurate with the performance of the PDAF.

In the fifth embodiment, a microlens LNZ221D has the bottom surface BTM20 formed in a square shape (Lx=Ly) where the length in the first direction (X direction) and the length in the second direction (Y direction) are equal. The angle between the first light incident surface LSI11 (plane abcd) and the bottom surface BTM20 (plane cdgh) is about 90 degrees, for example 80 to 90 degrees. Similarly, the angle between the first light incident surface LSI 12 (plane efgh) and the bottom surface BTM 20 (plane cdgh) is about 90 degrees, for example, 80 to 90 degrees. This configuration allows a very small fraction of the light to enter the photoelectric converting region PD1 from the first light incident surface LSI11 (plane abcd) or the first light incident surface LSI12 (plane efgh). To further cut the rays of light that may penetrate or be reflected by the first light incident surface LSI 11 (plane abcd) or the first light incident surface LSI 12 (plane efgh), the planes abcd and efgh may be coated with a black absorbing material.

Thus, in the fifth embodiment, the shape of the light spot is rectangular, for example, a rectangle corresponding to the shape of the aperture, so that it is possible to reduce unwanted light from the reflection by the metal shield MTLS at large incident angles.

Moreover, according to the fifth embodiment, it is possible to more appropriately compensate the performance degradation at the edge of the image plane occurred at large CRAs by adjusting the inclination angle of the input plane. The anisotropic design of the microprism also allows the focus spot to fit the aperture, and when the shape of the focus spot matches the shape of the aperture, the image quality degradation due to stray light can be minimized.

### Sixth Embodiment

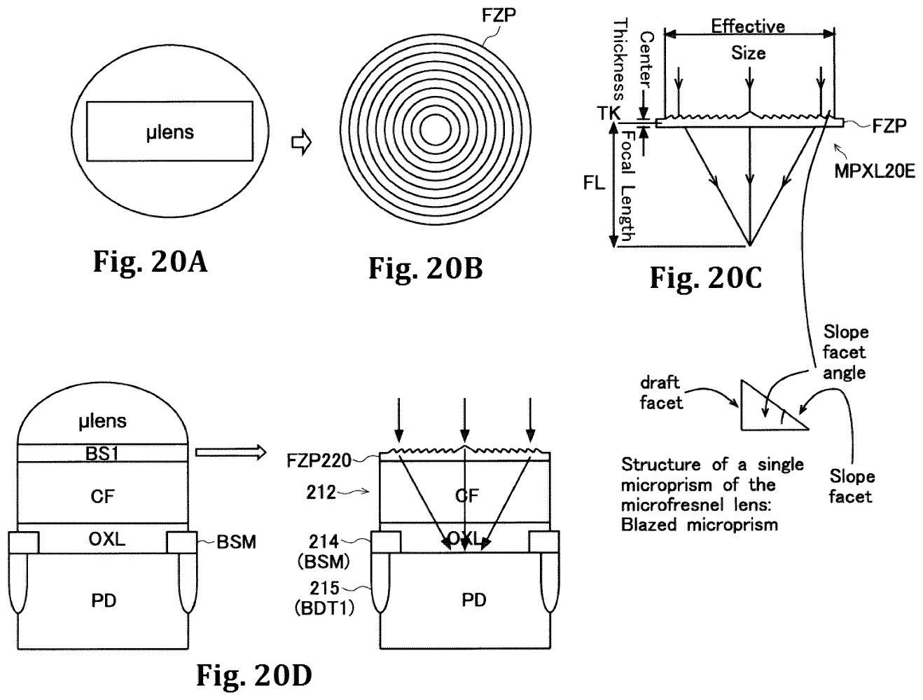

FIGS. 20A to 20C illustrate a schematic configuration example of a solid-state imaging device (CMOS image sensor) relating to a sixth embodiment of the invention, showing structures and functions of an existing microlens and a Fresnel zone plate (FZP) as a diffractive optical element that also serves as a microlens. FIG. 20A is a top view, and FIGS. 20B and 20C are side views.

The sixth embodiment differs from the first to fifth embodiments in the following points. In the first to fifth embodiments, the lens parts in the lens part array are the microlenses LNS221 to LNS224. Whereas in the sixth embodiment, lens parts LNS220E in a lens part array 220E is Fresnel zone plates FZP220 (FZP221 to FZP224), which are diffractive optical elements.

In other words, in the sixth embodiment, as shown in FIG. 20B, the Fresnel zone plates FZP220 (FZP221-FZP224) using diffractive and binary optical technology are used instead of the conventional microlenses whose shapes are identical at any pixel positions in the pixel array and the microlenses of the first and other embodiments whose shapes vary depending on the position of the corresponding pixel in the pixel array.

For example, a micro-Fresnel lens (FZP) can be formed by modifying a microlens and it can focus the light at the same location with a thinner converging element. Adjustment of position dependency of the converging characteristics (e.g., focal length) of individual elements can be achieved by changing the length and angle of the slope facet. Brazing of the individual microlens elements (the draft facets are approximately perpendicular to the base) is performed to avoid loss of light due to reflection from the input surface of the micro-Fresnel lens.

In the case of the Fresnel zone plate FZP220, the thickness TK is sufficiently small so that the control of the focal length FL is performed by adjusting the width and number of zones ZN, not the curvature or material of the plate. The number of zones ZN can also be brazed to control the number of focal points.

In CIS design generally, it is necessary to determine the shape, size, and location of the light spot incident on the surface of the photodetector (PD) based on a specific application. Compared to conventional refractive microlenses alone, diffractive optical elements (DOEs) offer more degrees of freedom with respect to the shape of the intensity profile of the light reaching a specific target plane (e.g., PD surface in the case of CIS, metal grid, etc.). DOEs typically introduce a spatially varying phase profile into the incident light beam.

The phase profile can be computationally designed to ensure that the desired intensity pattern reaches the PD surface under specific conditions. A correctly designed DOEs can implement any lens profile and can operate as a low dispersion, high refractive index material. The use of DOEs reduces the design size, the weight, and the number of requiring elements. Functionally, combining the DOEs with conventional refractive optics provides better control of chromatic and monochromatic aberrations and higher resolution.

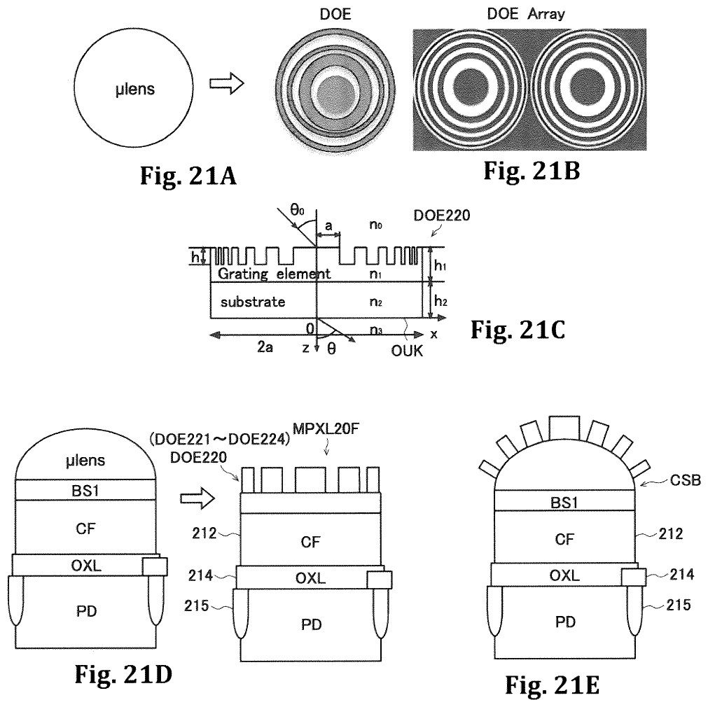

The diagram on the right side in FIG. 20A shows the Fresnel zone plate (FZP) that forms the basis of many DOEs. FIG. 20C shows an analog profile of a surface relief DOE structure that serves as a lens and uses the optical principles of the FZP in its operation. In use, such a structure can be efficiently fabricated as binary circular gratings, as shown in FIGS. 21A to 21E, which will be discussed later. The optical efficiency of this structure can be as high as that of an analog profile Fresnel lens by adding, for example, phase level 4 or 8. The F #(focal length/diameter) of the Fresnel lens is determined by its limit dimensions (minimum feature size that can be manufactured). In practice, however, such a limitation is eliminated by using a phase step of an integer multiple of 2π.

According to the sixth embodiment, similarly to the above described advantageous effects of the first to fifth embodiments, it is possible to manufacture the lens part array without complicated work, which in turn has the advantage of making the manufacture of the pixel part easily. It also makes it possible to reduce crosstalk between adjacent pixels since the substrate for the microlenses is not necessary. Furthermore, the focal length FL of the converging element can be effectively shortened to focus on the metal shield or BSM required for the PDAF applications. Since the focal length and focus size can be easily changed, the incidence angle dependence of the PDAF pixel output can be easily modified to minimize the effects of crosstalk. In addition, by using the optical component array in a sheet form, it is possible to control more precisely than the conventional method of manufacturing microlens arrays and thereby images without shading can be obtained, which results in an improved performance.

According to the sixth embodiment, the shape of each Fresnel lens can be easily modified depending on the position where the Fresnel lens is situated. In this way, it is possible to more appropriately compensate the performance degradation in the edge regions of the image plane occurred at large CRAs.

The shape of the Fresnel lens is preferably determined such that the target portion of the exit pupil of the imaging lens can be clearly recognized.

### Seventh Embodiment

FIGS. 21A to 21D illustrate a schematic configuration example of a solid-state imaging device (CMOS image sensor) relating to a seventh embodiment of the invention, showing structures and functions of an existing microlens and a diffractive optical element (DOE) that also serves as a microlens. FIG. 21A shows their diffraction state, FIG. 21B is a top view, FIG. 21C is a side view of the diffractive optical element (DOE), and FIGS. 21D and 21E are simplified sections of the solid-state imaging device.

The seventh embodiment differs from the first to fifth embodiments in the following points. In the first to fifth embodiments, the lens parts in the lens part array are the microlenses LNS221 to LNS224. Whereas in this seventh embodiment, the lens parts LNS220 of the lens part array 220 are formed of diffractive optical elements DOE220 (DOE221 to DOE224) as binary optical elements.

In other words, in the seventh embodiment, as shown in FIGS. 21A to 21E, the diffractive optical elements DOE220 (DOE221 to DOE224), each of which is formed by an array of grating structural units whose periods vary, are used instead of the conventional microlenses whose shapes are identical at any positions of pixels in the pixel array and the microlenses of the first embodiment whose shapes vary depending on the position of the corresponding pixel in the pixel array.

The focal length FL and spot size SPZ of the diffractive optical element DOE220 are controlled by designing the period change and the height of the grating lines. The advantages of the structure of the diffractive optical element DOE220 over the structure of the conventional microlens array are as follows. The conventional microlens process can be used to fabricate small-sized pixels (sub-microscale) and a large number of pixels (necessary for 3D), while height and curvature are limited by the pixel pitch. It is also possible to obtain a focal spot at the diffraction limit. For example, PDAF applications require effective control of the focal spot size to remove microlens profile errors. AFM measurements indicate that the actual microlens profile may differ from an ideal profile required. This can be a particular problem when one or more photodiode PDs share a single microlens.

The FZPs or DOEs can also be implemented using binary optical techniques to which VLSI semiconductor fabrication techniques are applied. They can be fabricated on optical films using the fabrication techniques described herein.

As shown in FIGS. 21A to 21D, various zones can be modeled using the surface relief grating structure whose period locally varying. FIG. 21A shows a top view of the optical element that can be used in place of the microlens. Several such elements can be combined to form a two-dimensional array. The two-dimensional array can be formed on an optical film using semiconductor process techniques such as lithography and micromachining, as shown in FIG. 21B. FIG. 21C shows a vertical section of the element and includes a description of the design variables. In general, the element consists of two parts, 1) the grating element GE and 2) the substrate SB. The design variables include: the period, the spatial variation of the period, the height (h) of the surface relief; the thickness (h1) of the grating and the width (2a) of the substrate (h2) in the central zone; the material of the grating (refractive index, n1); the material of the medium between two consecutive grating lines (refractive index, n0); and the material of the substrate of the grating (refractive index, n2). The refractive index of the material under the substrate is n3. FIG. 21D shows a new pixel model in which the conventional microlens is replaced by a circular grating such as the DOE structure. The optical film of the DOE array as shown in FIG. 21B can be placed on either a flat (FIG. 21D) or curved (FIG. 21E) substrate CSB.

According to the seventh embodiment, similarly to the above described advantageous effects of the first to fifth embodiments, it is possible to manufacture the lens part array without complicated work, which in turn has the advantage of making the manufacture of the pixel part easily. It also makes it possible to reduce crosstalk between adjacent pixels since the substrate for the microlenses is not necessary. Furthermore, the focal length FL of the converging element can be effectively shortened to focus on the metal shield or BSM required for the PDAF applications. Since the focal length and focus size can be easily changed, the incidence angle dependence of the PDAF pixel output can be easily modified to minimize the effects of crosstalk. In addition, by using the optical component array in a sheet form, it is possible to control more precisely than the conventional method of manufacturing microlens arrays and thereby images without shading can be obtained, which results in an improved performance.

According to the seventh embodiment, the shape of each DOE can be easily modified depending on the position where the DOE is situated in the array. In this way, it is possible to more appropriately compensate the performance degradation in the edge regions of the image plane occurred at large CRAs.

The shape of the DOE is preferably determined such that the target portion of the exit pupil of the imaging lens can be clearly recognized.

### Eighth Embodiment

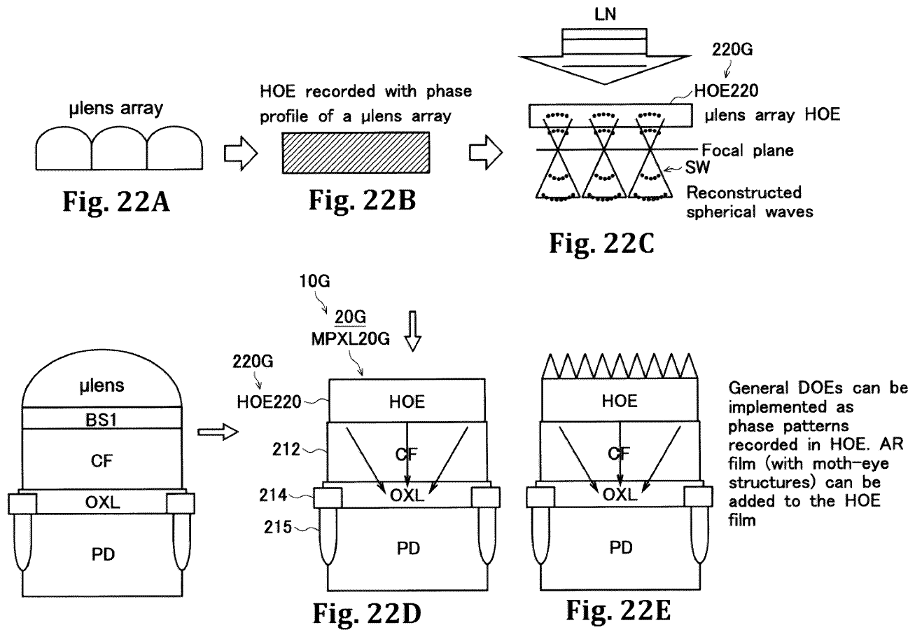

FIGS. 22A to 22D illustrate a schematic configuration example of a solid-state imaging device (CMOS image sensor) relating to an eighth embodiment of the invention, showing structures and functions of an existing microlens and a diffractive optical element (DOE) that also serves as a microlens. FIGS. 22A to 22C show the diffraction state, and FIGS. 22D and 22E are side views.

The eighth embodiment differs from the first to fifth embodiments in the following points. In the first to fifth embodiments, the lens parts in the lens part array are the microlenses LNS221 to LNS224. Whereas in this eighth embodiment, lens parts LNS220F of a lens part array 220G are formed of holographic optical elements HOE220 (HOE221 to HOE224) as the diffractive optical elements.

In other words, in the eighth embodiment, as shown in FIGS. 22A to 22E, the holographic optical elements HOE220 (HOE221-HOE224), which are computationally (programmatically) designed and configured using a PC, are used instead of the conventional microlenses whose shapes are identical at any positions of pixels in the pixel array and the microlenses of the first embodiment whose shapes vary depending on the position of the corresponding pixel in the pixel array.

In this example, the Fresnel zone plate FZP is recorded as a phase profile of the holographic material. Microlens profiles can be designed for both collimated light or diverging spherical waves.

Advantages of this embodiment are as follows. The necessary functions of the microlens array can be implemented on an optical film, as described above. The optical film can then be bonded to the pixel array. In this way, a more efficient manufacturing process for a microlens array than conventional manufacturing processes can be achieved. Moreover, the above configuration facilitates implementation of nonlinear microlens shift (computational design). Since the holographic optical element HOE220 can be fabricated in a flat photopolymer film form, it is possible to solve the problems caused by a microlens profile that is not ideal. It also allows precise control to obtain the same sensitivity among the subpixels in a superpixel system. The superpixel is a small region of in which pixels of similar color and texture are grouped together. By dividing the input image into the superpixels, it is possible to divide the image into small regions that reflect the positional relationships of similar color pixels. The sub-pixel refers to each point of one color of RGB included in a single pixel of a display. In the field of image processing, images are sometimes processed not in pixel units but as virtual units of sub-pixels, which is smaller than the pixel.

In this embodiment, the holographic optical element HOE 220 is another class of DOE designed by recording a desired phase profile of the optical material onto a photosensitive material such as a photopolymer. The phase profile corresponding to the microlens array can be generated by interfering an appropriate object light with a reference light.

FIG. 22B shows a transmissive flat-volume grating that encodes an interference fringe pattern corresponding to a microlens array. FIG. 22C shows a CIS device in which conventional microlenses are replaced by appropriately designed holographic optical elements HOEs. As shown in FIG. 22C, when the recorded interference pattern is illuminated by natural light LN, spherical waves SW are transmitted and generated, forming an array of focal points in a desired focal plane. This technology can be implemented in an optical film using the manufacturing techniques described in the first embodiment. The optical film can be bonded or incorporated into the CIS device design. The optical film can be bonded to the top of the pixels (pixel part) using optical cement or optical adhesive that has a matched refractive index. Alternatively, ARS and optical elements such as HOEs can be fabricated integrally and simultaneously.

According to the eighth embodiment, similarly to the above described advantageous effects of the first to fifth embodiments, it is possible to manufacture the lens part array without complicated work, which in turn has the advantage of making the manufacture of the pixel part easily. It also makes it possible to reduce crosstalk between adjacent pixels since the substrate for the microlenses is not necessary. Furthermore, the focal length FL of the converging element can be effectively shortened to focus on the metal shield or BSM required for the PDAF applications. Since the focal length and focus size can be easily changed, the incidence angle dependence of the PDAF pixel output can be easily modified to minimize the effects of crosstalk. In addition, by using the optical component array in a sheet form, it is possible to control more precisely than the conventional method of manufacturing microlens arrays and thereby images without shading can be obtained, which results in an improved performance.

### Ninth Embodiment

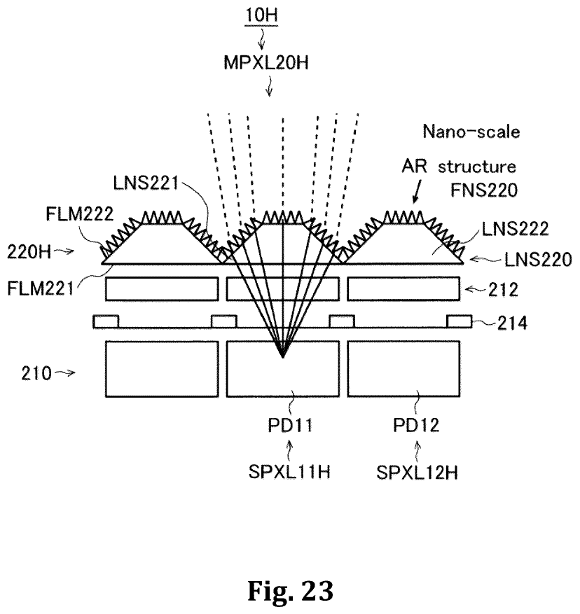

FIG. 23 schematically shows an example configuration of a solid-state imaging device (a CMOS image sensor) relating to a ninth embodiment of the present invention.

The ninth embodiment differs from the fourth and fifth embodiments in the following points. In the first to fifth embodiments, no antireflection film is formed on the light incident side of the microlenses LNS221 to LNS224, which are the lens parts LNS220 formed in an array integrally with the first optical film FLM221.

Whereas in this ninth embodiment, the lens part array 220H has a second optical film FLM222 disposed on the light-illuminated surface (light incident surface side) of the first optical film FLM221 (laminated together). A fine structure FNS220 having an antireflection function is formed on the second optical film FLM222 in the area corresponding to the light-illuminated surface (light incident surface side) of the microlenses LNS221 to LNS224 forming the lens parts LNS220.

Alternatively, in the ninth embodiment, the lens part array 220H may adopt a configuration in which the fine structure FNS220 having the antireflection function is integrally formed on the optical film FLM221 in the region corresponding to the light-illuminated surface (light incident surface side) of the microlenses LNS221 to LNS224 that form the lens parts LNS220 on the light-illuminated surface (light incident surface side) of the optical film FLM221 without using the second optical film.

The antireflection by such fine structure is also called Anti-Reflection Structure (ARS), as mentioned above (see, for example, Non-patent Literature 1: “In-Vehicle Technology” Vol, No. 7, 2019, pp 26-pp 29).

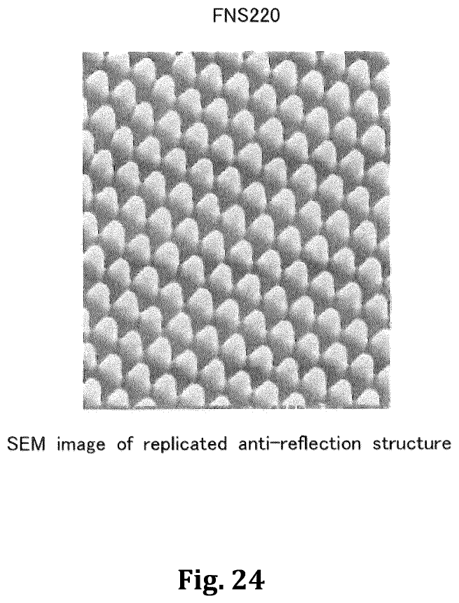

FIG. 24 shows an example of an AR (Anti-Reflection) structure formed on a film that can be employed as the fine structure of the ninth embodiment.

The fine structure FNS220 is formed on the light-illuminated surface (light incident surface side) of the microlenses LNS221 to LNS224 that form the lens parts LNS220. The fine structure FNS220 has a 3D fine structure such as a so-called moth-eye type nanocone array. This fine structure FNS220 can be fabricated, for example, from optically transparent materials using the same manufacturing equipment as that of FIG. 12. For example, a lithography technique using laser lithography is used to actively create regular patterns.

The layer including the moth-eye structure serves as a layer of refractive index distribution material (behaves like a gradient refractive index material). The small conical nanocones are arranged in a two-dimensional array. Because the period of the nanocone array is shorter than the wavelength of light (X), higher-order diffraction or scattering does not occur. However reflection losses at the light incident surface of the optical element are effectively reduced over a wide band of wavelengths and angles.

When rays of light enter a transparent resin or glass substrate, a difference in refractive index between the air and the substrate causes reflected light at the interface between the air and the substrate, which results in the reflection of outside light and reduces visibility. To suppress reflected light at the interface, an optical thin film utilizing the principle of light interference is used to prevent reflection. The phase of reflected light at the top of the thin film and the phase of reflected light at bottom of the thin film are inverted to cancel the amplitude of the reflected light. However, since this method is dependent on the wavelength and angle of the incident light, the reflected light may increase at some incident condition of the external light. In general, it is necessary to use a multilayer thin film to suppress reflection at a wide range of wavelengths or a wide range of incident angles (desirable for CIS). In addition, when an optical resin is used, the choice of materials is limited. This tends to make such multilayer thin-film antireflection coatings expensive for CIS applications.

Whereas when the fine structure is formed on the interface of the substrate as in the ninth embodiment, although a diffraction occurs as a result of light response as a wave due to the structure with a certain size, when the ARS structure is smaller than the wavelength of the external light within the plane of the base material, the light propagating through the substrate will no longer cause diffraction. The light incident and propagating at the interface responds as if the refractive index of the substrate is gradually changing in the direction of the light. Since the interface is seen blurred due to the gradual change in the refractive index, a broadband and highly functional antireflection performance can be obtained with little dependence on the wavelength and angle of the incident external light (see the above Non-patent Literature 1).

Thus, the fine structure FNS 220 includes the function of gradually changing the refractive index for the incident light in the direction the light travels.

The ninth embodiment has the above described advantageous effects of the first to fifth embodiments, and furthermore it is possible to reduce reflection loss on the light incident surface of the lens part, which improves quantum efficiency and facilitates the manufacturing of the pixel parts.

### Tenth Embodiment

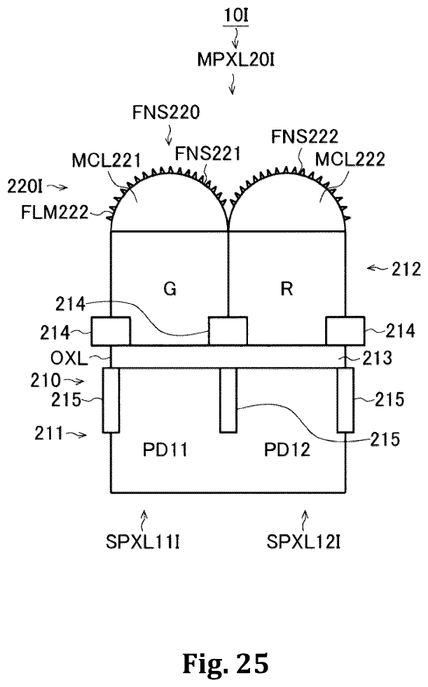

FIG. 25 schematically shows an example configuration of a solid-state imaging device (a CMOS image sensor) relating to a tenth embodiment of the invention.

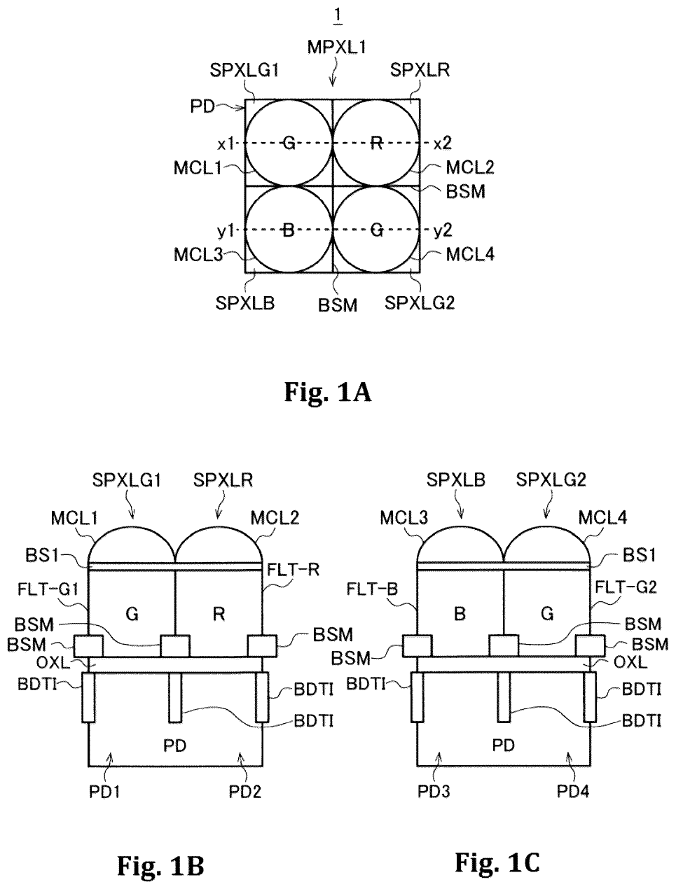

The tenth embodiment differs from the ninth embodiment in the following points. In the ninth embodiment, the fine structure FNS220 as the antireflection film is formed directly or via the second optical film FLM222 on the light incident surface side of the microlenses LNS221 to LNS224, which are the lens parts LNS220 formed in an array integrally with the optical film FLM221.

Whereas in the tenth embodiment, the lens part array 220I does not use the optical film FLM221, and the lens part LNS220 is formed of microlenses MCL220 (MCL221 to MCL224) in place of the microlenses LNS221 to LNS224 of FIG. 1.

According to the tenth embodiment, it is possible to reduce reflection loss on the light incident surface of the lens parts, which in turn facilitates the manufacturing of the pixel part.

The solid-state imaging devices 10, 10A to 10I described above can be applied, as imaging devices, to electronic apparatuses such as digital cameras, video cameras, mobile terminals, surveillance cameras, and medical endoscope cameras.

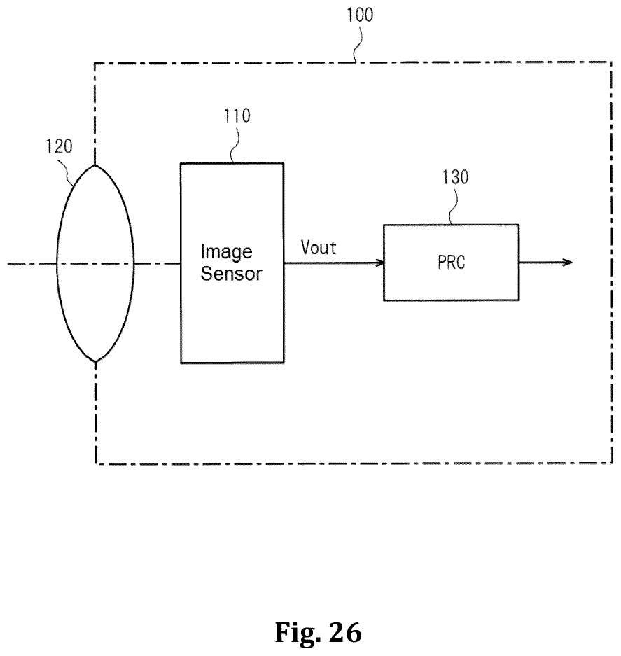

FIG. 26 shows an example configuration of an electronic apparatus including a camera system to which the solid-state imaging devices according to the embodiments of the present invention can be applied.

As shown in FIG. 26, the electronic apparatus 100 includes a CMOS image sensor 110 that can be constituted by any of the solid-state imaging devices 10, 10A to 10I relating to the embodiments of the present invention. The electronic apparatus 100 further includes an optical system (such as a lens) 120 for redirecting the incident light to the pixel region of the CMOS image sensor 110 (to form a subject image). The electronic apparatus 100 includes a signal processing circuit (PRC) 130 for processing the output signals from the CMOS image sensor 110.

The signal processing circuit 130 performs predetermined signal processing on the output signals from the CMOS image sensor 110. The image signals resulting from the processing in the signal processing circuit 130 can be handled in various manners. For example, the image signals can be displayed as a video image on a monitor having a liquid crystal display, printed by a printer, or recorded directly on a storage medium such as a memory card.

As described above, if any of the above-described solid-state imaging devices 10 and 10A to 10H is mounted as the CMOS image sensor 110, the camera system can achieve high-performance, compactness, and low-cost. Accordingly, the embodiments of the present invention can provide for electronic apparatuses such as surveillance cameras and medical endoscope cameras, which are used for applications where the cameras are installed under restricted conditions from various perspectives such as the installation size, the number of connectable cables, the length of cables and the installation height.

### LIST OF REFERENCE NUMBERS

10, 10A to 10I: solid-state imaging device, 20, 20A-20I: pixel part, MPXL20, 20A to 20I: multi-pixel, SPXL11 (A to I): first pixel, SPXL12 (A to I): second pixel, SPXL21 (A to I): third pixel, SPXL22 (A to I): fourth pixel, 210: pixel array, 211: photoelectric conversion part, 2111 (PD11): first photoelectric conversion part, 2112 (PD12): second photoelectric conversion part, 2112 (PD12): fourth photoelectric conversion part, 211: photoelectric conversion part, 2111 (PD11): first photoelectric conversion unit, 2112 (PD12): second photoelectric conversion part, 2113 (PD21): third photoelectric conversion part, 2114 (PD22): fourth photoelectric conversion part, 212: color filter part, 213: oxide film (OXL), 214: first separating part, 215: second separating part, 220: lens part array, FLM220: optical film, FLM221: first optical film, FLM222: second optical film, LNS220: lens part, LNS221 to LNS224: microlens (microprism), FZP221 to FZP224: Fresnel zone plate, DOE221 to DOE224: diffractive optical element, HOE221 to HOE224: holographic optical element, FNS220: fine structure, 30: vertical scanning circuit, 40: reading circuit, 50: horizontal scanning circuit, 60: timing control circuit, 70: reading part, 100: electronic apparatus, 110: CMOS image sensor, 120: optical system, 130: signal processing circuit (PRC).

1. A solid-state imaging device comprising:
a pixel part in which a plurality of pixels are arranged in an array, each pixel being configured to perform photoelectric conversion,
wherein the pixel part includes:
a pixel array in which a plurality of photoelectric conversion parts are arranged in an array, each photoelectric conversion part photoelectrically converting light of a predetermined wavelength incident from one side thereof; and
a lens part array including a plurality of lens parts arranged in an array, each lens part being disposed corresponding to one side of the corresponding photoelectric conversion part of the pixel array, each lens part condensing incident light onto the correspondingly arranged photoelectric conversion part to cause the light to enter the photoelectric conversion part from the one side of the photoelectric conversion part,
wherein the lens part array includes at least one optical film having predetermined optical function parts at least in a region where the lens parts are to be formed, the optical film is formed in a single body to extend over a plurality of the lens parts at least in a part of the lens part array.

2. The solid-state imaging device of claim 1, wherein the lens part includes a film-integrated optical element integrally formed with the at least one optical film as the optical function part, the film-integrated optical element condenses incident light onto the correspondingly arranged photoelectric conversion part to let the light enter from the one side of the photoelectric conversion part, and
wherein a shape of the film-integrated optical element varies depending on a position of the corresponding pixel in the pixel array.

3. The solid-state imaging device of claim 2, wherein, for an incident light beam having a spatially uniform intensity distribution, the film-integrated optical element is formed such that a first incident light amount mainly incident from a first direction of the pixel array and a second incident light amount mainly incident from a second direction orthogonal to the first direction become equal.

4. The solid-state imaging device of claim 2, wherein the film-integrated optical element is formed such that a first incident light amount mainly incident from a first direction of the pixel array and a second incident light amount mainly incident from a second direction orthogonal to the first direction become different from each other.

5. The solid-state imaging device of claim 3, wherein the film-integrated optical element includes a first light incident surface that admits light mainly from the first direction and a second light incident surface that admits light mainly from the second direction, and
wherein at least one of the first incident light amount or the second incident light amount is adjusted by a shape of at least corresponding one of the first light incident surface or the second light incident surface.

6. The solid-state imaging device of claim 2, wherein the film-integrated optical element is formed of an aspherical microlens whose shape varies depending on the position of the corresponding pixel in the pixel array.

7. The solid-state imaging device of claim 2, wherein the film-integrated optical element is formed in a frustum whose top faces a light incident side, and
wherein a vertex angle and an edge length are adjusted depending on the position of the corresponding pixel in the pixel array.

8. The solid-state imaging device of claim 2, wherein the lens part includes a diffractive optical element as the film-integrated optical element integrally formed with the at least one optical film as the optical function part, the film-integrated optical element condenses incident light onto the correspondingly arranged photoelectric conversion part to let the light enter from the one side of the photoelectric conversion part.

9. The solid-state imaging device of claim 8, wherein the diffractive optical element is formed of a Fresnel lens.

10. The solid-state imaging device of claim 8, wherein the diffractive optical element is formed of a binary optical element.

11. The solid-state imaging device of claim 8, wherein the diffractive optical element is formed of a holographic optical element.

12. The solid-state imaging device of claim 2, wherein a fine structure having an antireflection function is formed on a light-illuminated surface of the film-integrated optical element.

13. The solid-state imaging device of claim 1, wherein the lens part includes:
a microlens causing light to enter the corresponding photoelectric conversion part; and
the optical function part formed in the optical film disposed on an light-illuminated surface of the microlens,
wherein the optical function part is formed of a fine structure that has an antireflection function.

14. The solid-state imaging device of claim 12, wherein the fine structure has a function of gradually changing a refractive index for incident light in a direction the light travels.

15. A method for manufacturing a solid-state imaging device, the solid-state imaging device including a pixel part in which a plurality of pixels configured to perform photoelectric conversion are arranged in an array, the pixel part including a pixel array, and a lens part array disposed on light incident side of the pixel array,
the method comprising:
a pixel array fabrication step in which pixels are fabricated in an array, each pixel including a photoelectric conversion part that photoelectrically converts light of a predetermined wavelength incident from one side; and
a lens part array fabrication step in which lens parts are fabricated in an array, each lens part being disposed corresponding to one side of the corresponding photoelectric conversion part of the pixel array, each lens part condensing incident light onto the corresponding photoelectric conversion part to cause the light to enter the photoelectric conversion part from the one side of the photoelectric conversion part,
wherein, the lens part array fabrication step includes an optical film forming step in which at least one optical film having predetermined optical function parts at least in a region where the lens parts are to be formed is formed, the optical film being formed in a single body to extend over a plurality of the lens parts at least in a part of the lens part array.

16. An electronic apparatus comprising:
a solid-state imaging device; and
an optical system for forming a subject image on the solid-state imaging device,
wherein the solid-state imaging device includes a pixel part in which a plurality of pixels are arranged in an array, each pixel being configured to perform photoelectric conversion,
wherein the pixel part includes:
a pixel array in which a plurality of photoelectric conversion parts are arranged in an array, each photoelectric conversion part photoelectrically converting light of a predetermined wavelength incident from one side thereof; and
a lens part array including a plurality of lens parts arranged in an array, each lens part being disposed corresponding to one side of the corresponding photoelectric conversion part of the pixel array, each lens part condensing incident light onto the correspondingly arranged photoelectric conversion part to cause the light to enter the photoelectric conversion part from the one side of the photoelectric conversion part,
wherein the lens part array includes at least one optical film having predetermined optical function parts at least in a region where the lens parts are to be formed, the optical film is formed in a single body to extend over a plurality of the lens parts at least in a part of the lens part array.

17. An optical film fabricated by the optical film forming step of the method of claim 15.
